(19) United States
(12) Patent Application Publication
(10) Pub. No.: US 2025/0293134 A1
(43) Pub. Date: Sep. 18, 2025

(54) SEMICONDUCTOR DEVICE

(71) Applicant: FUJI ELECTRIC CO., LTD., Kawasaki-shi (JP)

(72) Inventor: Ryoichi KATO, Matsumoto-city (JP)

(73) Assignee: FUJI ELECTRIC CO., LTD., Kawasaki-shi (JP)

(21) Appl. No.: 19/221,320

(22) Filed: May 28, 2025

Related U.S. Application Data
(63) Continuation of application No. PCT/JP2024/016409, filed on Apr. 26, 2024.

(30) Foreign Application Priority Data
Jun. 16, 2023 (JP) 2023-099694

(51) Int. Cl. H01L 23/498; H01L 23/14

(52) U.S. Cl. CPC H01L 23/49833; H01L 23/145

(57) ABSTRACT

A semiconductor device includes parallel plate-shaped first and second terminals, a first insulating member including a first portion disposed between a lower surface of the first terminal and an upper surface of the second terminal and a second portion extending a predetermined distance outward in a first direction beyond an end of the first terminal, a second insulating member having a contact portion disposed between the lower surface of the first terminal and the upper surface of the second terminal and being in contact with both the first and second portions, and a case fixing all the terminals and insulating members. The first insulating member is in direct contact with one of the first and second terminals and is not in contact with the other of the first and second terminals. The second insulating member is in contact with the other of the first and second terminals.

### CROSS-REFERENCE TO RELATED APPLICATION

This application is a continuation application of International Application PCT/JP2024/016409 filed on Apr. 26, 2024, which designated the U.S., which claims priority to Japanese Patent Application 2023-099694, filed on Jun. 16, 2023, the entire contents of which are incorporated herein by reference.

### BACKGROUND OF THE INVENTION

### 1. Field of the Invention

The embodiments discussed herein relate to a semiconductor device.

### 2. Background of the Related Art

A semiconductor device includes a terminal unit that includes an external terminal, an insulating sheet, and another external terminal, which are stacked in a stepwise manner from the bottom up in order. The other external terminal, which serves as the topmost layer, has the rear surface that includes an end portion along the side of its outer end and another portion different from the end portion. As the rear surface approaches the tip, the end portion gets closer to the front surface than the other portion. This reduces the electric field strength at the outer end of the external terminal serving as the lowermost layer (see, for examples, Japanese Laid-open Patent Publication No. 2022-125790). Further, a semiconductor device includes two main terminals, each with a projecting portion projecting from a sealing resin body. These main terminals are disposed so as to cancel their magnetic fluxes caused by main current flowing through the main terminals (see, for example, Japanese Laid-open Patent Publication No. 2019-207922). Still further, a conductive connection material including a metal foil sandwiched by resin compositions is disposed between terminals, a heat treatment is conducted to adjust the distance between the terminals, and then the resin compositions are solidified at a temperature lower than the melting point of the metal foil. By doing so, high electrical connection between the terminals and high insulation reliability between adjacent terminals are achieved (see, for example, Japanese Laid-open Patent Publication No. 2011-165879).

Still further, positive and negative external electrodes are joined to plate-shaped positive and negative external connection terminals of a semiconductor device, respectively, their entire opposing surfaces. The positive and negative external connection terminals and the corresponding positive and negative external electrodes are electrically connected with their surfaces parallel to each other and with an electrical insulation portion disposed between the external connection terminals and an electrical insulation portion disposed between the external electrodes. This reduces the resistance at the junctions between the external connection terminals and the corresponding external electrodes, and ensures the insulation between the external connection terminals and the insulation between the external electrodes even when their distances are small (see, for example, Japanese Laid-open Patent Publication No. 2007-234693).

Still further, a semiconductor device includes first and second terminals that project from a sealing body in the same direction and are disposed adjacent to each other with a space therebetween. The first and second terminals include first and second exposed portions exposed outside the sealing body, and portions of the first and second exposed portions located on the sealing body side are sheathed with first and second sheathed parts, respectively. The distance from the front end of the second sheathed part to the sealing body is longer than the distance from the front end of the first sheathed part to the sealing body. This ensures the insulation performance between the terminals, eliminates the need to increase the size of the device, and suppresses an increase in inductance (see, for example, Japanese Laid-open Patent Publication No. 2021-180252).

In a laminated portion in which three electrode lead-out terminals are laminated with insulating resin sheets therebetween, the end surface position of an edge of one electrode lead-out terminal adjacent to an insulating resin sheet is located inside the end surface position of an edge of the insulating resin sheet. In addition, the end surface position of an edge of the other electrode lead-out terminal adjacent to the insulating resin sheet is located in alignment with or outside the end surface position of the edge of the insulating resin sheet. This ensures a sufficient insulation creepage distance between the terminals (see, for example, Japanese Laid-open Patent Publication No. 2010-157565).

A semiconductor device has a laminated structure in which an anode conductor, an insulating sheet, and a cathode conductor are arranged in this order. An insulating cap having a flange part for ensuring a creepage distance and barrier parts for ensuring a spatial distance is disposed between the anode conductor and the insulating sheet. This makes it possible to enhance the reduction effect of inductance and suppress surge voltage, thereby eliminating the need for a fuse and a snubber circuit (see, for example, Japanese Laid-open Patent Publication No. 2005-065414). Still further, in a semiconductor device, a mica-based insulating member is sandwiched by conductor boards of different polarities, the ends of the conductor boards are surrounded by the insulating member, and a resin insulating material fills each gap between mica-based hole insulating members and connection through-holes. In addition, a mica-based sheet is attached to each of the front and rear sides of the laminated conductor board. Thus obtained laminated conductor board is less likely to suffer an insulation breakdown (see, for example, Japanese Laid-open Patent Publication No. 2005-130542).

### SUMMARY OF THE INVENTION

According to an aspect, there is provided a semiconductor device, including: a plate-shaped first terminal having opposite upper and lower surfaces that are parallel to each other; a plate-shaped second terminal having opposite upper and lower surfaces that are parallel to each other, the upper surface of the second terminal facing and being parallel to the lower surface of the first terminal; a first insulating member including a first portion being disposed between the lower surface of the first terminal and the upper surface of the second terminal, and a second portion extending a predetermined distance outward beyond an end of the first terminal in a first direction parallel to the lower surface of the first terminal; a second insulating member having a contact portion disposed between the lower surface of the first terminal and the upper surface of the second terminal, the contact portion being in contact with both the first portion and the second portion of the first insulating member; and a case fixing the first terminal, the second insulating member, the first insulating member, and the second terminal, wherein the first insulating member is in direct contact with one of the first terminal or the second terminals and is not in n contact with the other of the first terminal or the second terminals, and wherein the second insulating member is in contact with the other of the first terminal or the second terminals.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is an oblique view of a semiconductor device according to a first embodiment;

FIG. 2 is a side view of the semiconductor device according to the first embodiment;

FIG. 3 is a plan view of the semiconductor device according to the first embodiment;

FIG. 4 is a plan view of a stacked terminal unit included in the semiconductor device according to the first embodiment;

FIG. 5 is a first lengthwise sectional view of the stacked terminal unit included in the semiconductor device according to the first embodiment;

FIG. 6 is a second lengthwise sectional view of the stacked terminal unit included in the semiconductor device according to the first embodiment;

FIG. 7 is a widthwise sectional view of the stacked terminal unit included in the semiconductor device according to the first embodiment;

FIG. 8 is a view for describing the electric field strength of a stacked terminal unit according to a first comparison example;

FIG. 9 is a widthwise sectional view of a stacked terminal unit according to a second comparison example;

FIG. 10 is a widthwise sectional view of a stacked terminal unit included in the semiconductor device according to the first embodiment (modification 1-1);

FIG. 11 is a widthwise sectional view of a stacked terminal unit included in the semiconductor device according to the first embodiment (modification 1-2);

FIG. 12 is a widthwise sectional view of a stacked terminal unit included in the semiconductor device according to the first embodiment (modification 1-3);

FIG. 13 is a plan view of a stacked terminal unit included in a semiconductor device according to a second embodiment;

FIG. 14 is a first lengthwise sectional view of the stacked terminal unit included in the semiconductor device according to the second embodiment;

FIG. 15 is a widthwise sectional view of the stacked terminal unit included in the semiconductor device according to the second embodiment;

FIG. 16 is a side view of a semiconductor device according to a third embodiment;

FIG. 17 is a plan view of the semiconductor device according to the third embodiment;

FIG. 18 is a lengthwise sectional view of a stacked terminal unit included in the semiconductor device according to the third embodiment;

FIG. 19 is a widthwise sectional view of the stacked terminal unit included in the semiconductor device according to the third embodiment; and

FIG. 20 is a widthwise sectional view of a stacked terminal unit included in the semiconductor device according to the third embodiment (modification 3-1).

### DETAILED DESCRIPTION OF THE INVENTION

Hereinafter, embodiments will be described with reference to the accompanying drawings. In the following description, the terms “front surface” and “upper surface” refer to the X-Y plane facing upward (the +Z direction) in semiconductor devices 1 and 1a illustrated in drawings. Similarly, the term “up” refers to the upward direction (the +Z direction) in the semiconductor devices 1 and 1a illustrated in the drawings. The terms “rear surface” and “lower surface” refer to the X-Y plane facing downward (the −Z direction) in the semiconductor devices 1 and 1a illustrated in the drawings. Similarly, the term “down” refers to the downward direction (the −Z direction) in the semiconductor devices and la illustrated in the drawings. The same directionality applies to other drawings as appropriate. The terms “front surface,” “upper surface,” “up,” “rear surface,” “lower surface,” “down,” and “side surface” are used for convenience to describe relative positional relationships, and do not limit the technical concept of the embodiments. For example, the terms “up” and “down” are not always related to the vertical directions to the ground. That is, the “up” and “down” directions are not limited to those related to the gravity direction. In addition, in the following description, the term “main component” refers to a component contained at 80% or more by volume. The expression “being substantially the same” permits a variation of +10%. The expressions “being vertical” and “being parallel” permit a variation of ±10%.

### First Embodiment

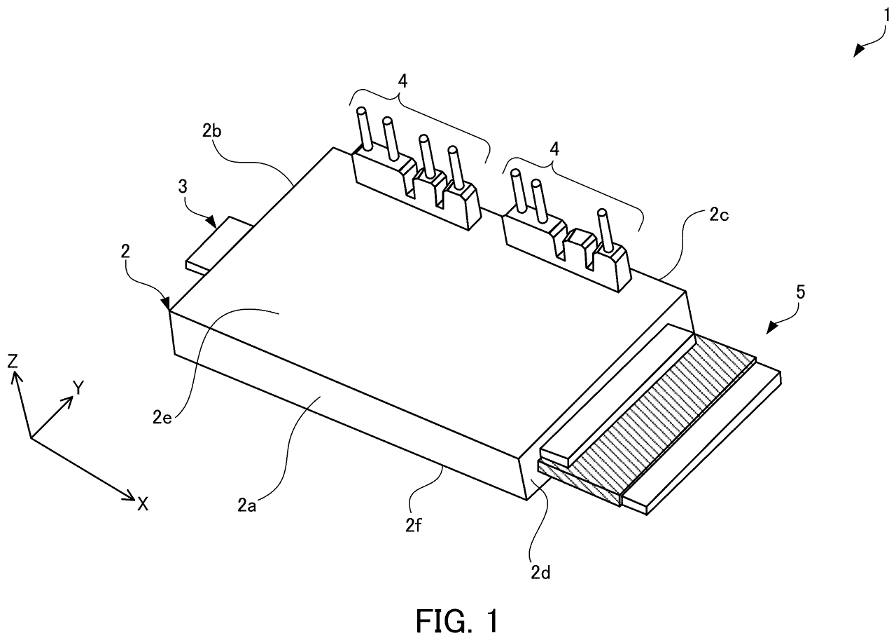

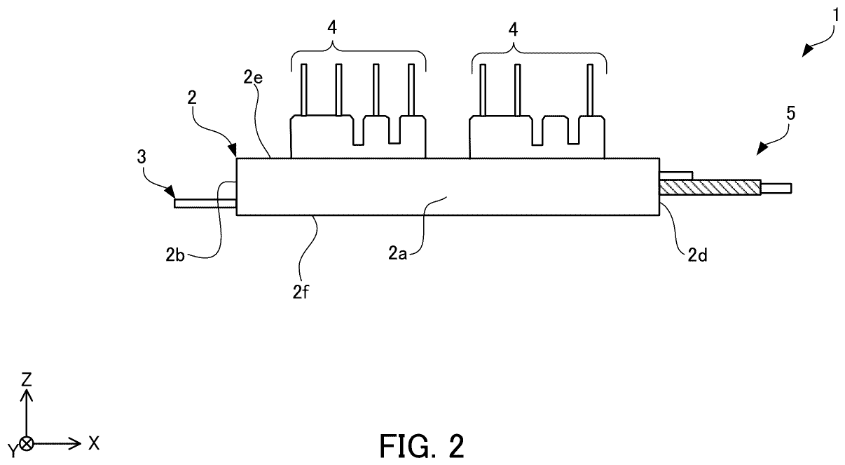

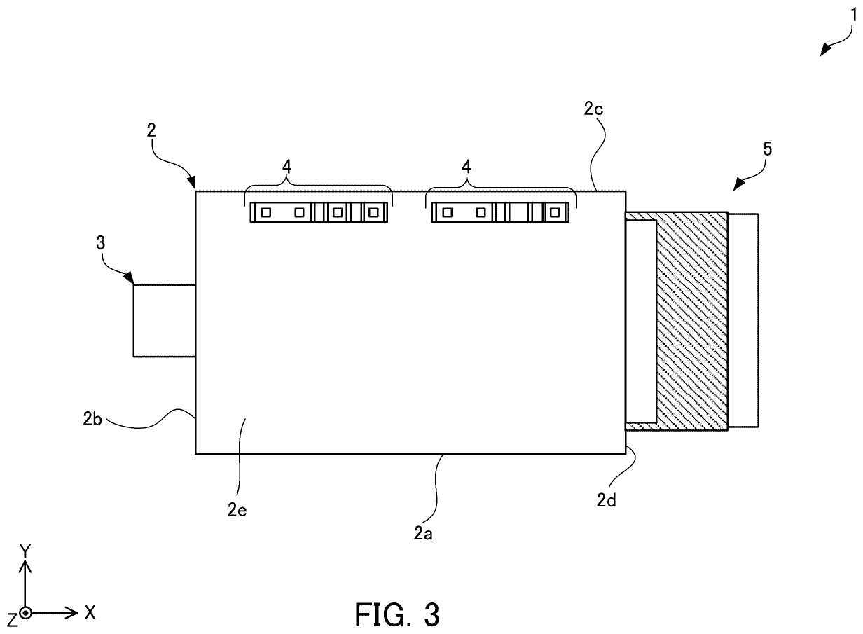

A semiconductor device 1 according to a first embodiment will be described with reference to FIGS. 1 to 3. FIG. 1 is an oblique view of the semiconductor device according to the first embodiment. FIG. 2 is a side view of the semiconductor device according to the first embodiment. FIG. 3 is a plan view of the semiconductor device according to the first embodiment. In this connection, the side view of FIG. 2 illustrates the semiconductor device 1 of FIG. 1 as seen in the +Y direction. The plan view of FIG. 3 illustrates the semiconductor device 1 of FIG. 1 as seen in the −Z direction.

The semiconductor device 1 may include at least a case 2, an output terminal 3, control terminals 4, and a stacked terminal unit 5. The case 2 seals an insulated circuit substrate and a semiconductor chip (neither is illustrated). For example, the case 2 is made of a thermosetting resin as its main component. Examples of the thermosetting resin include epoxy resin, phenolic resin, maleimide resin, and polyester resin. The thermosetting resin may further contain a filler. As an example, the filler may be ceramics. Such ceramics are insulating and have high thermal conductivity. For example, the case 2 is formed in a cuboid shape using the thermosetting resin and includes side surfaces 2a to 2d, a top surface 2e, and a bottom surface 2f. Its corners may be rounded or chamfered. The top surface 2e and bottom surface 2f are rectangular in plan view. The side surfaces 2a to 2d surround the four sides of each of the top surface 2e and bottom surface 2f in order in plan view. The side surfaces 2a and 2c are parallel to the lengthwise direction (±X direction) (corresponding to the long sides of the case 2), whereas the side surfaces 2b and 2d are parallel to the widthwise direction (±Y direction) of the case 2 (corresponding to the short sides of the case 2).

The insulated circuit substrate and semiconductor chip sealed in the case 2 will now be described. The insulated circuit substrate includes an insulating plate, conductive patterns formed on the front surface of the insulating plate, and a metal plate formed on the rear surface of the insulating plate. The insulating plate and metal plate are rectangular in plan view. The corners of each of the insulating plate and metal plate may be rounded or chamfered. In plan view, the metal plate is smaller in size than the insulating plate and is formed inside the insulating plate.

The insulating plate is made of an insulating material with high thermal conductivity. This insulating plate is made of ceramics. Examples of the ceramics include aluminum oxide, aluminum nitride, and silicon nitride.

A plurality of conductive patterns are formed on the front surface of the insulating plate. The plurality of conductive patterns each have a predetermined shape. The semiconductor chip is mounted on one of the plurality of conductive patterns, so that the semiconductor chip and the plurality of conductive patterns form a circuit that achieves a desired function of the semiconductor device 1. The conductive patterns are made of a metal with high electrical conductivity. Examples of the metal include copper, aluminum, and an alloy containing at least one of these as a main component. The surfaces of the conductive patterns may be plated to improve their corrosion resistance. Examples of the plating material used here include nickel, a nickel-phosphorus alloy, and a nickel-boron alloy.

These conductive patterns are formed on the front surface of the insulating plate in the following manner. A metal layer is formed on the front surface of the insulating plate, and is then processed, e.g., etched to obtain the plurality of conductive patterns in predetermined shapes. Alternatively, the plurality of conductive patterns cut out from a metal layer in advance may be press-bonded to the front surface of the insulating plate. The corners of the plurality of conductive patterns may be rounded or chamfered.

The metal plate is formed on the rear surface of the insulating plate. The metal plate is rectangular. In plan view, the area of the metal plate is smaller than that of the insulating plate, and is larger than that of a region where the plurality of conductive patterns are formed. The corners of the metal plate may be rounded or chamfered. The metal plate is smaller in size than the insulating plate and is formed on the entire surface of the insulating plate except the edge portion thereof. The metal plate is made of a metal with high electrical conductivity. Examples of this metal include copper, aluminum, and an alloy containing at least one of these. The surface of the metal plate may be plated to improve its corrosion resistance. Examples of the plating material used here include nickel, a nickel-phosphorus alloy, and a nickel-boron alloy.

As the insulated circuit substrate configured as above, a direct copper bonding (DCB) substrate or an active metal brazed (AMB) substrate may be used, for example.

The semiconductor chip includes a power device element that is made of silicon. For example, the power device element is a reverse conducting-insulated gate bipolar transistor (RC-IGBT). An RC-IGBT has both the function of an IGBT, which is a switching element, and the function of a freewheeling diode (FWD), which is a diode element. Such a semiconductor chip has a control electrode (gate electrode) and an output electrode (emitter electrode) serving as a main electrode on the front surface thereof. The semiconductor chip also has an input electrode (collector electrode) serving as a main electrode on the rear surface thereof. The control electrode may be provided along one side of the front surface of the semiconductor chip (or at the center of one side thereof), for example. The output electrode may be provided in the center of the front surface of The input electrode may be the semiconductor chip. provided in an area including the center of the rear surface of the semiconductor chip.

Instead of the RC-IGBT, the semiconductor chip may include a set of a switching element and a diode element. For example, the switching element is an IGBT or metal-oxide-semiconductor field-effect a power transistor (MOSFET). For example, such a semiconductor chip has an input electrode (drain electrode or collector electrode) serving as a main electrode on the rear surface thereof, and also has a control electrode (gate electrode) and an output electrode (source serving as a main electrode or emitter electrode) electrode on the front surface thereof. For example, the diode element is a Schottky barrier diode (SBD) or a P-intrinsic-N (PiN) diode, and is used as an FWD. Such a semiconductor chip has an output electrode (cathode electrode) serving as a main electrode on the rear surface thereof, and also has an input electrode (anode electrode) serving as a main electrode on the front surface thereof.

Alternatively, the semiconductor chip may include a power MOSFET as a switching element. In such a semiconductor chip, the body diode of the power MOSFET may achieve the same function as the FWD of an RC-IGBT. This semiconductor chip has a control electrode (gate electrode) and an output electrode (source electrode) serving as a main electrode on the front surface thereof. The semiconductor chip also has an input electrode (drain electrode) serving as a main electrode on the rear surface thereof. Such a semiconductor chip may preferably be made of silicon carbide.

The semiconductor chip is bonded to a predetermined conductive pattern of the insulated circuit substrate using a bonding material. In addition, the control electrode and output electrode of the semiconductor chip may be connected to predetermined conductive patterns with wires.

The bonding material may be solder or a sintered metal. Lead-free solder is used as the solder. For example, the lead-free solder contains, as its main component, an alloy containing at least two of tin, silver, copper, zinc, antimony, indium, and bismuth. In addition, the solder may contain an additive. Examples of the additive include nickel, germanium, cobalt, and silicon. The solder containing the additive improves its wettability, gloss, and bond strength, which improves reliability. For example, the sintered metal contains, as its main component, at least one of iron, copper, aluminum, titanium, nickel, tungsten, and molybdenum.

The output terminal 3 is electrically connected to a predetermined conductive pattern of the insulated circuit substrate inside the case 2, and extends outward from the side surface 2b of the case 2. The output terminal 3 extends in a direction (the −X direction) perpendicular to the side surface 2b. In this connection, the predetermined conductive pattern is electrically connected to the output electrode of the semiconductor chip. At least the portion of the output terminal 3 extending outward from the side surface 2b of the case 2 is flat plate-shaped. A through-hole may be formed in the outward-extending portion of the output terminal 3. The output terminal 3 is made of a metal with high electrical conductivity. Examples of the metal include copper, aluminum, and an alloy containing at least one of these as its main component. The surface of the output terminal 3 may be plated to improve its corrosion resistance. Examples of the plating material used here include nickel, a nickel-phosphorus alloy, and a nickel-boron alloy.

A control terminal 4 is electrically connected to a predetermined conductive pattern of the insulated circuit substrate inside the case 2, and extends outward from the top surface 2e of the case 2 in a direction (+Z direction) perpendicular to the top surface 2e. The predetermined conductive pattern is electrically connected to the control electrode of the semiconductor chip. The predetermined conductive pattern may be electrically connected to the output electrode of the semiconductor chip. In this case, a sense current that flows through the semiconductor chip flows through the control terminal 4 electrically connected to the predetermined conductive pattern.

A plurality of control terminals 4 may be provided adjacent to and along the side surface 2c on the top surface 2e. The lower portions of the control terminals 4 close to the top surface 2e may be protected by protective parts. These protective parts may be made of the same material as the case 2. The control terminals 4 are made of a metal with high electrical conductivity. Examples of the metal include copper, aluminum, and an alloy containing at least one of these as its main component. The surfaces of the control terminals 4 may be plated to improve their corrosion resistance. Examples of the plating material used here include nickel, a nickel-phosphorus alloy, and a nickel-boron alloy.

The stacked terminal unit 5 is electrically connected to a predetermined conductive pattern of the insulated circuit substrate inside the case 2, and extends outward from the side surface 2d of the case 2. The stacked terminal unit 5 extends in a direction (+X direction) perpendicular to the side surface 2d of the case 2. The stacked terminal unit 5 is connected to an external positive electrode and an external negative electrode. The predetermined conductive pattern is electrically connected to the output electrode and input electrode of the semiconductor chip.

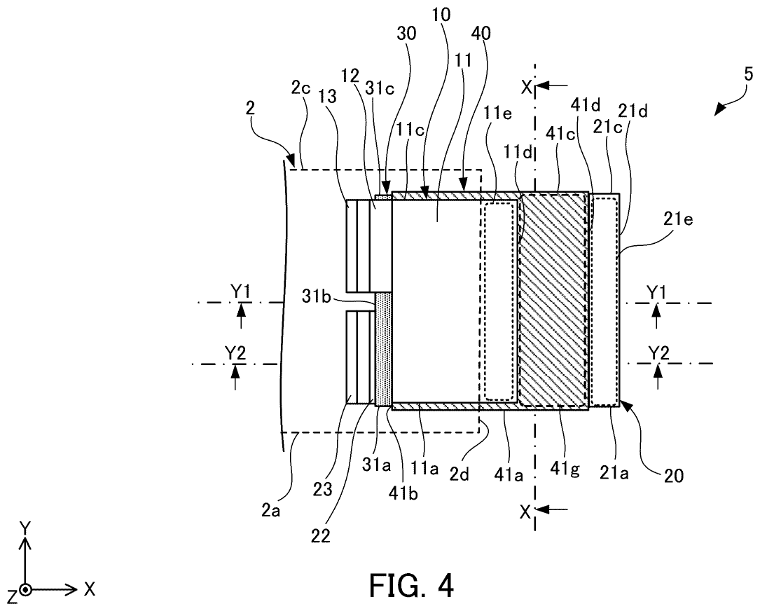

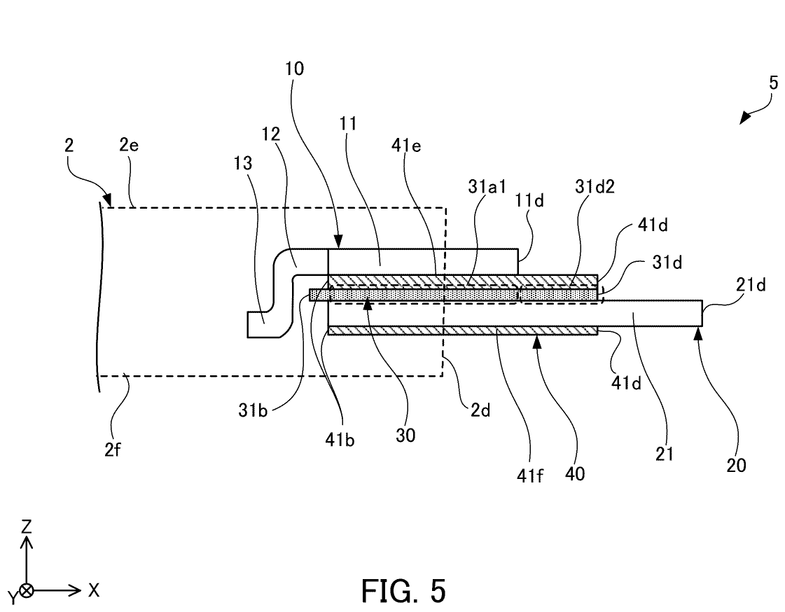

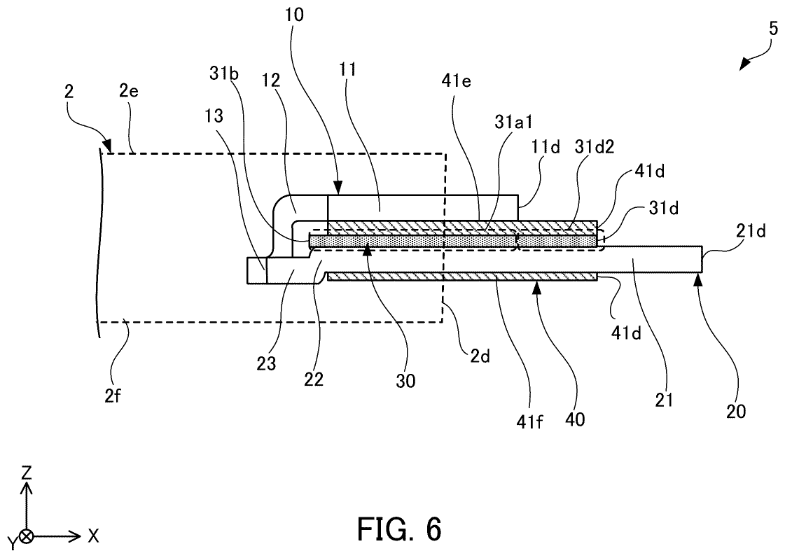

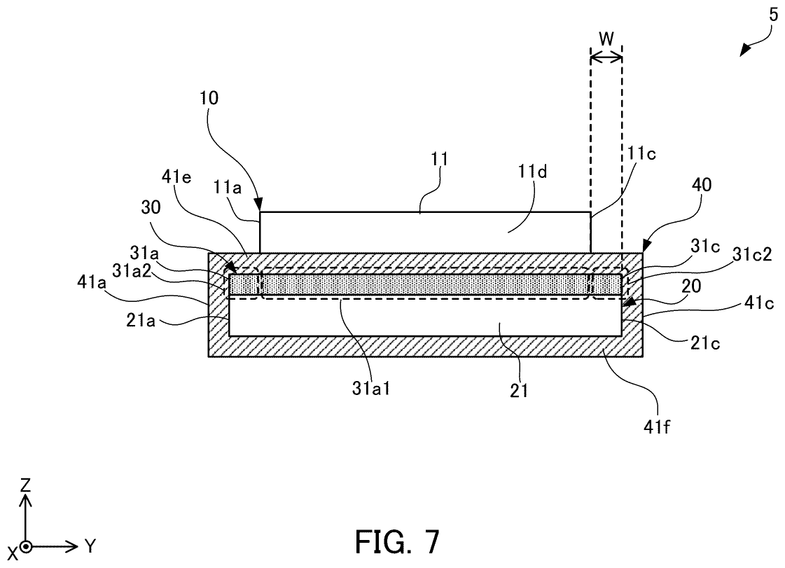

The above stacked terminal unit 5 will now be described in detail with reference to FIGS. 4 to 7. FIG. 4 is a plan view of the stacked terminal unit included in the semiconductor device according to the first embodiment. FIG. 5 is a first lengthwise sectional view of the stacked terminal unit included in the semiconductor device according to the first embodiment. FIG. 6 is a second lengthwise sectional view of the stacked terminal unit included in the semiconductor device according to the first embodiment. FIG. 7 is a widthwise sectional view of the stacked terminal unit included in the semiconductor device according to the first embodiment. In FIGS. 4 to 6, the part covered by the case 2 is indicated by a dashed line. The sectional views of FIGS. 5 and 6 are views taken along the dash-dotted lines Y1-Y1 and Y2-Y2 of FIG. 4, respectively. The sectional view of FIG. 7 is a view taken along the dash-dotted line X-X of FIG. 4.

The stacked terminal unit 5 includes a first terminal 10, a second terminal 20, a first insulating member 30, and a second insulating member 40. The first terminal 10 integrally includes a conducting portion 11, linking portion 12, and a joining portion 13. The a first terminal 10 is substantially uniform in thickness throughout. The first terminal 10 extends outward from the side surface 2d of the case 2. In addition, a portion of the first terminal 10 extends inward from the side surface 2d of the case 2. The inward-extending portion of the first terminal 10 from the side surface 2d of the case 2 is secured to the case 2. The first terminal 10 has an exposed region, which is exposed as described later.

The conducting portion 11 is rectangular in plan view and is flat plate-shaped. In plan view, the conducting portion 11 includes terminal edge portions 11a and 11c at respective opposite sides of the rectangular front surface and rear surface thereof, and a terminal outer end portion 11d at the respective tips of the front surface and rear surface.

The opposite sides here are sides that are parallel to the extending direction (+X direction) of the stacked terminal unit 5. That is, the terminal edge portions 11a and 11c are substantially parallel to the side surfaces 2a and 2c of the case 2. In addition, the tips are the outermost ends in the extending direction (+X direction) of the stacked terminal unit 5. That is, the terminal outer end portion 11d is substantially parallel to the side surfaces 2b and 2d of the case 2. The portion of the front surface of the conducting portion 11 extending from the side surface 2d of the case 2 is an exposed region 11e (see FIG. 4). For example, a negative terminal (N terminal) may be externally connected to the exposed region 11e.

The linking portion 12 is provided on the terminal edge portion 11c side, at the end of the conducting portion 11 opposite to the terminal outer end portion 11d (in the −X direction). The width of the linking portion 12 in the ±Y direction may be between 30% and 50% of that of the conducting portion 11.

The joining portion 13 is rectangular in plan view and is flat plate-shaped. The joining portion 13 is located closer to the bottom surface 2f of the case 2 than is the conducting portion 11, when viewed in the +Y direction. The joining portion 13 is integrally connected to the conducting portion 11, which is at a different height, through the linking portion 12. The joining portion 3 is joined to a predetermined conductive pattern of the insulated circuit substrate, not illustrated. In this connection, this joining may be achieved by joining using the above-mentioned bonding material or by ultrasonic joining.

The second terminal 20 integrally includes a conducting portion 21, a linking portion 22, and a joining portion 23. The second terminal 20 is substantially uniform in thickness throughout. The conducting portion 21 is rectangular in plan view, is flat plate-shaped, and is located opposite to the conducting portion 11 of the first terminal 10. In plan view, the conducting portion 21 includes terminal edge portions 21a and 21c at respective opposite sides of the rectangular front surface and rear surface thereof, and a terminal outer end portion 21d at the respective tips of the front surface and rear surface.

The opposite sides here are sides that are parallel to the extending direction (+X direction) of the stacked terminal unit 5. That is, the terminal edge portions 21a and 21c are substantially parallel to the side surfaces 2a and 2c of the case 2 and the terminal edge portions 11a and 11c of the first terminal 10. In addition, in the first embodiment, the conducting portion 21 has a greater width in the ±Y direction than the conducting portion 11 of the first terminal 10. That is, the terminal edge portions 21a and 21c of the conducting portion 21 are located further outside in the ±Y direction than the terminal edge portions 11a and 11c of the conducting portion 11 of the first terminal 10, respectively.

In addition, the tips here are the outermost ends in the extending direction (+X direction) of the stacked terminal unit 5. That is, the terminal outer end portion 21d is substantially parallel to the side surfaces 2b and 2d of the case 2 and the terminal outer end portion 11d of the first terminal 10. In addition, the terminal outer end portion 21d is located further outside (in the +X direction) than the terminal outer end portion 11d of the first terminal 10. That is, the conducting portion 21 has a greater length in the ±X direction (in the extending direction of the stacked terminal unit 5) than the conducting portion 11 of the first terminal 10. In plan view, the end portion of the conducting portion 21 opposite to the terminal outer end portion 21d may be aligned with the end portion of the first terminal 10 opposite to the terminal outer end portion 11d. The portion of the front surface of the conducting portion 21 extending from the case 2 and beyond the second insulating member 40 is an exposed region 21e (see FIG. 4). For example, a positive terminal (P terminal) may externally be connected to the exposed region 21e.

The linking portion 22 is provided on the terminal edge portion 21a side, at the end of the conducting portion 21 opposite to the terminal outer end portion 21d (in the −X direction). The width in the ±Y direction of the linking portion 22 may be between 30% and 50% of that of the conducting portion 21. Note that the linking portion 22 and the linking portion 12 of the first terminal 10 may have such widths as not to overlap each other in plan view, and may be formed to be continuous with the conducting portions 21 and 11, respectively, without overlapping each other.

The joining portion 23 is rectangular in plan view and is flat plate-shaped. The joining portion 23 is located closer to the bottom surface 2f of the case 2 than is the conducting portion 21, when viewed in the ±Y direction. The joining portion 23 is integrally connected to the conducting portion 21, which is at a different height, through the linking portion 22. The joining portion 23 is joined to a predetermined conductive pattern of the insulated circuit substrate, not illustrated. That is, the joining portion 23 may be at the same height as the joining portion 13 of the first terminal 10. In this connection, the joining may also be achieved by joining using the above-mentioned bonding material or by ultrasonic joining.

The first terminal 10 and second terminal 20 are made of a metal with high electrical conductivity. Examples of the metal include copper, aluminum, and an alloy containing at least one of these as its main component. The surfaces of the first terminal 10 and second terminal 20 may be plated to improve their corrosion resistance. Examples of the plating material used here include nickel, a nickel-phosphorus alloy, and a nickel-boron alloy.

The first insulating member 30 is provided between the front surface of the conducting portion 21 of the second terminal 20 and the rear surface of the conducting portion 11 of the first terminal 10. More specifically, the rear surface of the conducting portion 11 of the first terminal 10 is provided on the front surface of the first insulating member 30 with the second insulating member 40 therebetween. The first insulating member 30 is made of an insulating material as its main component. The first insulating member 30 is an insulating paper sheet (film) and is, for example, an aramid paper. The aramid paper is an insulating paper made of woven high-density aramid fibers. Alternatively, the aramid paper may be mica-based insulating paper.

The first insulating member 30 includes a first portion 31a1 and second portions 31a2, 31c2, and 31d2. In addition, the first insulating member 30 is rectangular in plan view, and includes an insulating edge portion 31a, an insulating inner end portion 31b, an insulating edge portion 31c, and an insulating outer end portion 31d, which surround the four sides of the first insulating member 30. The insulating edge portions 31a and 31c are provided at opposite sides of the first insulating member 30. The opposite sides here are sides that are parallel to the extending direction (+X direction) of the stacked terminal unit 5. That is, the insulating edge portions 31a and 31c are substantially parallel to the side surfaces 2a and 2c of the case 2, the terminal edge portions 11a and 11c of the first terminal 10, and the terminal edge portions 21a and 21c of the second terminal 20.

The first portion 31a1 of the first insulating member 30 is a portion located between the first terminal 10 and the second terminal 20. In the first embodiment, the first portion 31a1 corresponds to the conducting portion 11 of the first terminal 10. In the first embodiment, the first insulating member 30 has substantially the same width in the ±Y direction as the conducting portion 21 of the second terminal 20. That is, the insulating edge portions 31a and 31c of the first insulating member 30 are substantially aligned with the terminal edge portions 21a and 21c of the conducting portion 21 of the second terminal 20, respectively. Therefore, the first insulating member 30 has a greater width in the ±Y direction than the conducting portion 11 of the first terminal 10. That is, the insulating edge portions 31a and 31c of the first insulating member 30 are located further outside in the ±Y direction than the terminal edge portions 11a and 11c of the conducting portion 11 of the first terminal 10, respectively. The portions (for example, the regions enclosed by broken rectangles of FIG. 7) of the first insulating member 30 that extend outward (in the ±Y direction) beyond the terminal edge portions 11a and 11c of the conducting portion 11 of the first terminal 10 up to the insulating edge portions 31a and 31c are the second portions 31a2 and 31c2, respectively. In this connection, the second portions 31a2 and 31c2 of the first insulating member 30 extend, by width W, outward (in the ±Y direction) beyond the terminal edge portions 11a and 11c (ends of the bottom surface parallel to the second terminal 20) of the first terminal 10.

The insulating inner end portion 31b is a −X-side inner end of the first insulating member 30. That is, the insulating inner end portion 31b is substantially parallel to the side surfaces 2b and 2d of the case 2, the terminal outer end portion 11d of the first terminal 10, and the terminal outer end portion 21d of the second terminal 20. Furthermore, the insulating inner end portion 31b extends in the −X direction beyond the (−X side) end portion of the conducting portion 11 of the first terminal 10 opposite to the terminal outer end portion 11d and the (−X side) end portion of the conducting portion 21 of the second terminal 20 opposite to the terminal outer end portion 21d.

The insulating outer end portion 31d is a +X-side outer end portion of the first insulating member 30. That is, the insulating outer end portion 31d is substantially parallel to the side surfaces 2b and 2d of the case 2, the terminal outer end portion 11d of the first terminal 10, and the terminal outer end portion 21d of the second terminal 20. In addition, the insulating outer end portion 31d is located further outside (in the +X direction) than the terminal outer end portion 11d of the first terminal 10 and further inside (in the −X direction) than the terminal outer end portion 21d of the second terminal 20. The portion of the front surface of the first insulating member 30 exposed from the case 2 and beyond the conducting portion 11 of the first terminal 10 is an exposed region (reference numeral omitted). The portion (for example, the region enclosed by a broken rectangle of FIGS. 5 and 6) of the first insulating member 30 that extends outward (in the +X direction) beyond the terminal outer end portion 11d of the conducting portion 11 of the first terminal 10 up to the insulating outer end portion 31d is the second portion 31d2. The front surface of the second portion 31d2 of the first insulating member 30 is an exposed region (reference numeral omitted). The length of the second portion 31d2 of the first insulating member 30 in the ±X direction may be set such as to ensure the insulation between the terminal outer end portion 11d of the first terminal 10 and the second terminal 20. This length is around 10 mm, for example. Therefore, in plan view, the second portions 31a2, 31c2, and 31d2 are provided on the −Y side, +Y side, and +X side of the first portion 31a1.

The second insulating member 40 includes a portion (insulating upper portion 41e) disposed between the first terminal 10 and the second terminal 20. In addition, the insulating upper portion 41e of the second insulating member 40 is in contact with the upper surfaces of the first portion 31a1 and second portions 31a2, 31c2, and 31d2 of the first insulating member 30. Note that, in the first embodiment, the second

insulating member 40 includes the insulating upper portion 41e, which is in contact with each upper surface of the first portion 31a1 and second portions 31a2, 31c2, and 31d2, and surrounds the first insulating member 30 and the second terminal 20 together. As illustrated in FIG. 7, the second insulating member 40 integrally includes the insulating upper portion 41e, an insulating edge portion 41a, an insulating edge portion 41c, and an insulating lower portion 41f, and surrounds the first insulating member 30 and the second terminal 20, when viewed in the −X direction.

The insulating upper portion 41e of the second insulating member 40 covers the front surface of the first insulating member 30 across the ±Y direction. In addition, the insulating edge portions 41a and 41c of the second insulating member 40 covers the insulating edge portions 31a and 31c of the first insulating member 30 and the terminal edge portions 21a and 21c of the conducting portion 21 of the second terminal 20 across the ±Z direction. In addition, the insulating lower portion 41f of the second insulating member 40 covers the rear surface of the conducting portion 21 of the second terminal 20 across the ±Y direction.

The second insulating member 40 is substantially uniform in length in the ±X direction throughout. The −X-side insulating inner end portion 41b of the second insulating member 40 is substantially aligned with the end portion of the first terminal 10 (conducting portion 11) opposite to the terminal outer end portion 11d. The −X-side insulating inner end portion 41b of the second insulating member 40 is substantially aligned with the end portion of the second terminal 20 (conducting portion 21) opposite to the terminal outer end portion 21d. In addition, the insulating outer end portion 41d of the second insulating member 40 is substantially aligned with the insulating outer end portion 31d of the first insulating member 30.

The second insulating member 40 is also made of an insulating material as its main component. In this connection, the second insulating member 40 may have lower insulation than the first insulating member 30. The second insulating member 40, however, needs to have higher flexibility than the first insulating member 30. That is, the second insulating member 40 has lower dielectric breakdown strength than the first insulating member 30. The second insulating member 40 has a lower Young's modulus than the first insulating member 30. For example, the second insulating member 40 may be a heat-shrinkable tube or an insulating tape. For example, the material here may be polyolefin or fluorine-based resin (PTFE).

In the stacked terminal unit 5 configured as described above, a negative terminal is connected to the exposed region 11e of the first terminal 10 and a positive terminal is connected to the exposed region 21e of the second terminal 20. The conducting direction of the first terminal 10 is opposite to that of the second terminal 20. The first insulating member 30 and the second insulating member 40 (insulating upper portion 41e) are provided between the first terminal 10 and the second terminal 20. Therefore, the stacked terminal unit 5 maintains the insulation between the first terminal 10 and the second terminal 20, which reduces inductance.

The above-described semiconductor device 1 is manufactured as follows. First, the components (first terminal 10, second terminal 20, first insulating member 30, and second insulating member 40) of the stacked terminal unit 5 are prepared. The first insulating member 30 is disposed on the front surface of the conducting portion 21 of the second terminal 20 and then these are surrounded by the second insulating member 40. The first terminal 10 is disposed on the second terminal 20 with the first insulating member 30 and second insulating member 40 therebetween. The semiconductor chip, output terminal 3, control terminals 4, and stacked terminal unit 5 are joined to predetermined conductive patterns of the insulated circuit substrate. At this time, wiring is performed on the insulated circuit substrate and the semiconductor chip using bonding wires. In the stacked terminal unit 5, the first insulating member 30 is disposed on the front surface of the conducting portion 21 of the second terminal 20, and these are surrounded by the second insulating member 40. As a result, the stacked terminal unit 5 has improved handleability.

Thus joined insulated circuit substrate is placed in a predetermined mold, and a sealing member is injected in the mold and is then solidified. By doing so, the insulated circuit substrate and semiconductor chip are sealed inside the mold, so that the output terminal 3, control terminals 4, and stacked terminal unit 5 are fixed. The mold is then removed, thereby obtaining the semiconductor device 1.

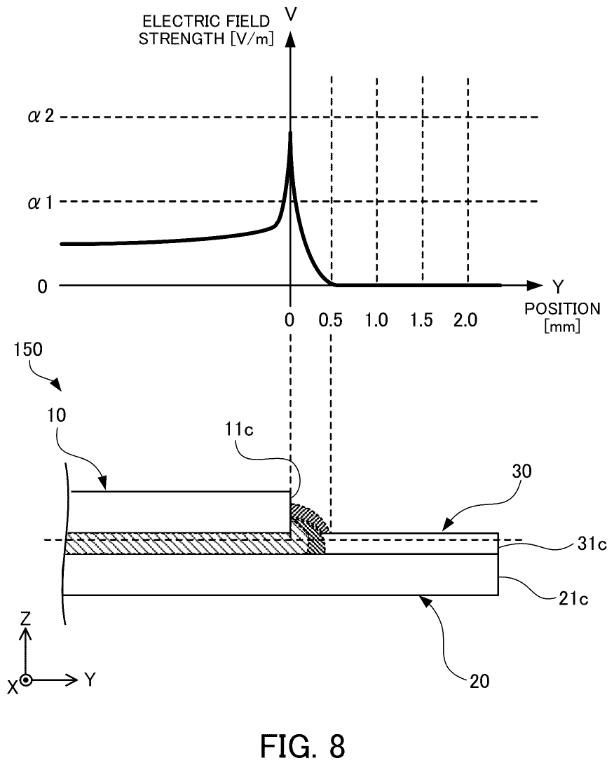

The following describes, as a first comparison example for the stacked terminal unit 5 of the first embodiment, a case where the second insulating member 40 is removed from the stacked terminal unit 5, with reference to FIG. 8. FIG. 8 is a view for describing the electric field strength of a stacked terminal unit according to the first comparison example. The lower part of FIG. 8 is a sectional view of a portion of a stacked terminal unit 150 around the terminal edge portion 11c of a first terminal 10 according to the first comparison example. This sectional view corresponds to the sectional view (FIG. 7) taken along the dash-dotted line X-X of FIG. 4. The dashed line parallel to the ±Y direction in this view indicates where the electric field strength is measured in the stacked terminal unit 150. Each hatched area in the view is an area where the electric field strength occurs. The upper part of FIG. 8 illustrates the relationship between electric field strength and distance (position) in the ±Y direction of the stacked terminal unit 150. Specifically, the horizontal axis Y represents the position (mm) in the Y direction of the stacked terminal unit 150, whereas the vertical axis V represents the electric field strength (V/m). The origin (0 mm) of the t horizontal axis corresponds to the position of the terminal edge portion 11c of the first terminal 10 included in the stacked terminal unit 150.

In the stacked terminal unit 150 of the first comparison example, the first terminal 10 is provided on the second terminal 20 with the first insulating member 30 therebetween. The first insulating member 30 extends outward beyond the terminal edge portion 11c of the first terminal 10. The insulating edge portion 31c of the first insulating member 30 is substantially aligned with the terminal edge portion 21c of the second terminal 20.

In this stacked terminal unit 150, for example, a negative terminal is connected to the first terminal 10 and a positive terminal is connected to the second terminal 20, and a current is made to flow. It is then seen that the electric field strength occurs in an area of the first insulating member 30 where the first terminal 10 and second terminal 20 overlap each other. Especially, it is seen that the electric field strength is the greatest at a position corresponding to the terminal edge portion 11c of the first terminal 10 in the first insulating member 30. As the position in the first insulating member 30 moves outward (in the +Y direction) from the terminal edge portion 11c of the first terminal 10, the electric field strength at that position decreases. Then, when the position is separated by more than 0.5 mm, there is little electric field strength.

It is seen from the above that, in the stacked terminal unit 150, the electric field strength increases significantly in the vicinity of the terminal edge portion 11c of the first terminal 10. Therefore, the stacked terminal unit 150 is unable to maintain the insulation between the terminal edge portion 11c of the first terminal 10 and the second terminal 20.

In addition, consider now the case where the first terminal 10 and the second terminal 20 in the stacked terminal unit 150 have the same width in the ±Y direction. In this case, the first insulating member 30 needs to have a sufficiently greater width in the ±Y direction than the first terminal 10 and second terminal 20, in order to ensure the insulation creepage distance between the first terminal 10 and the second terminal 20. Therefore, the stacked terminal unit 150 needs to have a certain width, which imposes a limit on downsizing.

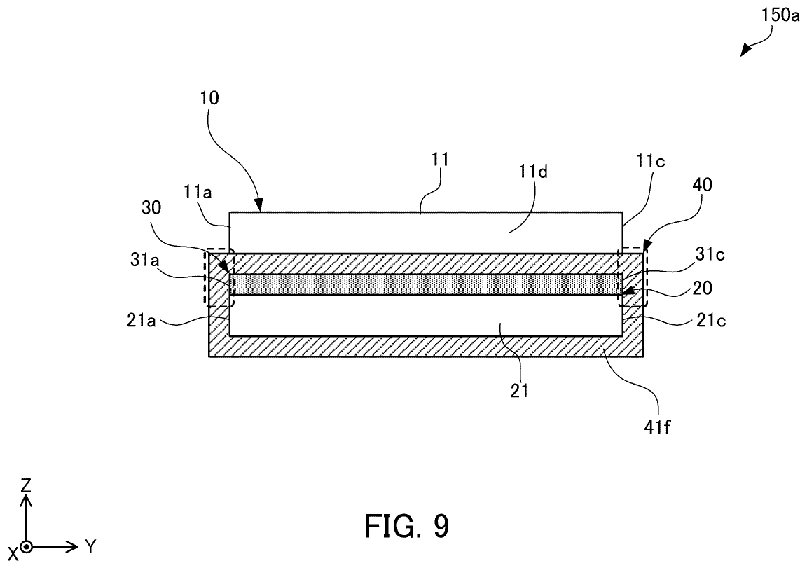

The following describes, as a second comparison example for the stacked terminal unit 150 of the first comparison example, a case where a second insulating member 40 is provided, with reference to FIG. 9. FIG. 9 is a widthwise sectional view of a stacked terminal unit according to the second comparison example. The sectional view of FIG. 9 is a view of a stacked terminal unit 150a at a location corresponding to the dash-dotted line X-X of FIG. 4.

In order to achieve downsizing of the stacked terminal unit 150 of the first comparison example, the stacked terminal unit 150a of the second comparison example is configured so that the first terminal 10, the second terminal 20, and the first insulating member 30 have the same width in the ±Y direction. In addition, the second insulating member 40 is provided to surround the first insulating member 30 and the second terminal 20 together, in order to improve insulation.

In this stacked terminal unit 150a, a negative terminal is connected to the first terminal 10 and a positive terminal is connected to the second terminal 20, and a current is made to flow. As described above, in the second insulating member 40, the electric field strength is the greatest at the terminal edge portions 11a and 11c of the first terminal 10. Therefore, the stacked terminal unit 150a may be damaged in the areas of the second insulating member 40 enclosed by the broken lines of FIG. 9. The damage to these areas increases the likelihood of failing to maintain the insulation between the first terminal 10 and the second terminal 20.

To deal with this, the above-described To deal with semiconductor device 1 includes the first terminal 10, the second terminal 20, the first insulating member 30, the second insulating member 40, and the case 2. The first terminal 10 and the second terminal 20 are plate-shaped, and the second terminal 20 is located opposite to the first terminal 10. The first insulating member 30 has the first portion 31a1 located between the first terminal 10 and the second terminal 20, and the second portions 31a2, 31c2, and 31d2 extending outward beyond ends of the bottom surface of the first terminal 10 parallel to the second terminal 20 by predetermined distances. The second insulating member 40 is partly disposed between the first terminal 10 and the second terminal 20, and is in contact with the first portion 31a1 and second portions 31a2, 31c2, and 31d2 of the first insulating member 30. The case 2 fixes the first terminal 10, the second insulating member 40, the first insulating member 30, and the second terminal 20. This reduces the likelihood of damage to the insulating edge portions 41a and 41c included in the second insulating member 40 corresponding the second portions 31a2 and 31c2. The first insulating member 30 has higher insulation than the second insulating member 40, and the first insulating member 30 and the second insulating member 40 are provided between the first terminal 10 and the second terminal 20. This makes it possible to keep the distance constant between the first terminal 10 and the second terminal 20, to alleviate the electric field concentration between the first terminal 10 and the second terminal 20 directly below the terminal edge portions 11a and 11c and terminal outer end portion 11d of the first terminal 10, and to maintain the insulation. Therefore, the stacked terminal unit 5 having the above-described configuration allows for a reduction in the width of the first insulating member 30 while ensuring the insulation creepage distance between the first terminal 10 and the second terminal 20, which achieves downsizing. Furthermore, it is achieved to alleviate the electric field concentration between the first terminal 10 and the second terminal 20. Thus, it is possible to reduce the size of the semiconductor device 1 including the stacked terminal unit 5 while maintaining the reliability of the semiconductor device 1.

Considering the result illustrated in FIG. 8, the above-described semiconductor device 1 is able to ensure the insulation more reliably in the case where the insulating edge portion 31c of the first insulating member 30 in the stacked terminal unit 5 is formed to extend beyond the first terminal 10 by 0.5 mm or more. That is, the widths (in the ±Y direction) of the extending second portions 31a2 and 31c2 and the length (in the ±X direction) of the extending second portion 31d2 in the stacked terminal unit 5 are preferably 0.5 mm or more.

In this connection, the stacked terminal unit 5 needs to have the exposed regions 11e and 21e on the +X side thereof for the connection of positive and negative terminals. In addition to the extension of the second portion 31d2 of the first insulating member 30 beyond the terminal outer end portion 11d of the first terminal 10 by 0.5 mm or more, the second portion 31d2 needs to be formed so as to ensure an insulation creepage distance (in the ±X direction) to maintain the insulation between the exposed region 11e of the first terminal 10 and the exposed region 21e of the second terminal 20.

In addition, the first embodiment provides the case where the insulating edge portion 41a, insulating upper portion 41e, insulating edge portion 41c, and insulating lower portion 41f of the second insulating member 40 have substantially the same thickness (see FIG. 7). The second insulating member 40 is not limited to this configuration, and the insulating edge portions 41a and 41c may have a greater thickness than the insulating upper portion 41e and insulating lower portion 41f.

In addition, the stacked terminal unit 5 of the first embodiment includes the first terminal 10, and the second terminal 20, which is surrounded together with the first insulating member 30 by the second insulating member 40 on the rear surface side of the first terminal 10. Components that are surrounded by the second insulating member 40 are not limited to these. For example, in the case where the first terminal 10 has a greater width in the ±Y direction than the second terminal 20, the first insulating member 30 that has the same width in the ±Y direction as the first terminal 10 may be disposed on the rear surface of the first terminal 10, and the first terminal 10 and the first insulating member 30 may be surrounded by the second insulating member 40. Then, the second terminal 20 may be provided on the rear surface of the second insulating member 40 surrounding the first terminal 10 and first insulating member 30. In this case, the terminal outer end portion 11d of the first terminal 10 surrounded by the second insulating member 40 may extend beyond the insulating outer end portion 41d in the +X direction, and the terminal outer end portion 21d of the second terminal 20 may extend beyond the terminal outer end portion 11d of the first terminal 10 in the +X direction.

The following describes some modifications of the stacked terminal unit 5 of the first embodiment. In each modification, a first terminal 10, a second terminal 20, a first insulating member 30, a second insulating member 40 may be made of the same materials as used in the first embodiment, unless otherwise noted.

### Modification 1-1

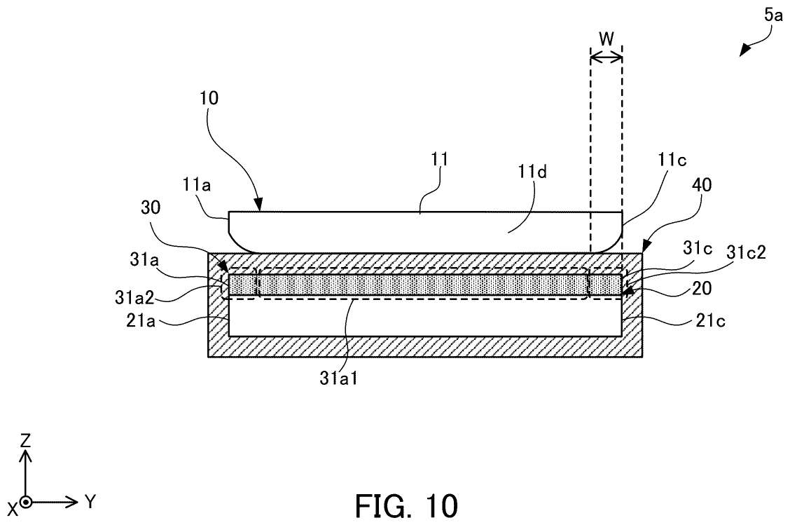

A stacked terminal unit 5a of a modification 1-1 will be described with reference to FIG. 10. FIG. 10 is a widthwise sectional view of the stacked terminal unit included in the semiconductor device according to the first embodiment (modification 1-1). More specifically, the sectional view of FIG. 10 is a view of the stacked terminal unit 5a at a location corresponding to the dash-dotted line X-X of FIG. 4.

Compared to the stacked terminal unit 5 of the first embodiment, the stacked terminal unit 5a of the modification 1-1 is formed so that the first terminal 10, second terminal 20, and first insulating member 30 have substantially the same width in the ±Y direction. The terminal edge portions 11a and 11c (end portions (edges) of the conducting portion 11 on the second terminal 20 side) of the first terminal 10 (conducting portion 11) in the stacked terminal unit 5a are chamfered on the rear surfaces thereof along the terminal edge portions 11a and 11c (in the ±X direction). In this connection, this chamfering may be C-chamfering or R-chamfering.

Therefore, the insulating edge portions 31a and 31c of the first insulating member 30 extend outward beyond the ±Y-side chamfered ends of the rear surface of the first terminal 10 (conducting portion 11) by width W. In other words, the terminal edge portions 11a and 11c of the first terminal 10 extend outward in the ±Y direction while moving away from the second portions 31a2 and 31c2 of the first insulating member 30.

As in the first embodiment, the stacked terminal unit 5a having the above-described configuration allows for a reduction in the width of the first insulating member 30 while ensuring the insulation creepage distance between the first terminal 10 and the second terminal which 20, achieves downsizing. Furthermore, it is achieved to alleviate the electric field concentration between the first terminal 10 and the second terminal 20.

Furthermore, the terminal edge portions 11a and 11c (the end portions (edges) of the conducting portion 11 on the second terminal 20 side) of the first terminal 10 (conducting portion 11) are chamfered on the rear surfaces thereof along the terminal edge portions 11a and 11c (in the ±X direction). By doing so, the first terminal 10 has a large cross section, compared to the stacked terminal unit 5. Thus, the stacked terminal unit 5a has an increased current capacity.

### Modification 1-2

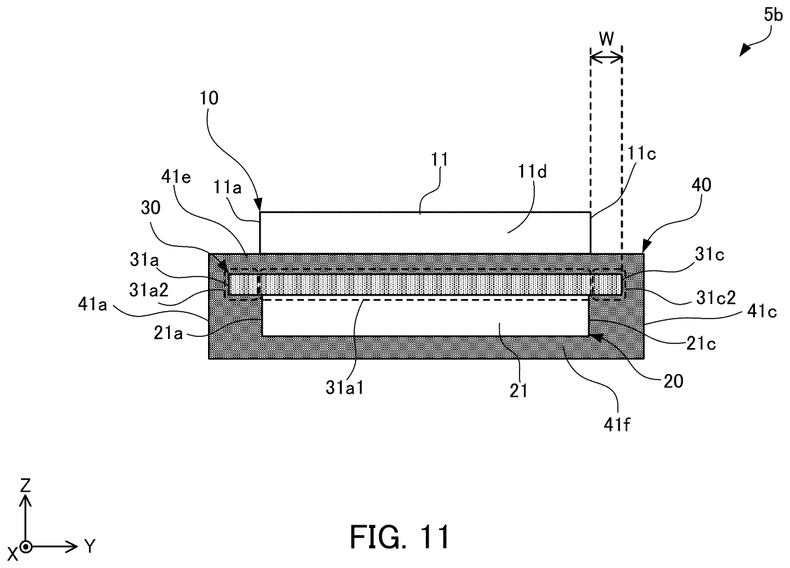

A stacked terminal unit 5b of a modification 1-2 will be described with reference to FIG. 11. FIG. 11 is a widthwise sectional view of the stacked terminal unit included in the semiconductor device according to the first embodiment (modification 1-2). More specifically, the sectional view of FIG. 11 is a view of the stacked terminal unit 5b at a location corresponding to the dash-dotted line X-X of FIG. 4.

Compared to the stacked terminal unit 5 of the first embodiment, the stacked terminal unit 5b of the modification 1-2 is formed so that the first terminal 10 and the second terminal 20 have substantially the same width in the ±Y direction. The first insulating member 30 has a greater width in the ±Y direction than the first terminal 10 and second terminal 20. That is, the second portions 31a2 and 31c2 of the first insulating member 30 extend outward (in the ±Y direction) beyond the terminal edge portions 11a and 11c of the first terminal 10 and the terminal edge portions 21a and 21c of the second terminal 20.

Furthermore, the stacked terminal unit 5b of the modification 1-2 is formed so that, when viewed in the −X direction, the four-side outer periphery of the second terminal 20 and the first insulating member 30, which is disposed on the front surface of the second terminal 20, is entirely surrounded by the second insulating member 40. In addition, the second insulating member 40 of the modification 1-2 is made of a thermosetting resin as its main component. The thermosetting resin has been described earlier, but here, for example, epoxy resin may be used. The first terminal 10 (conducting portion 11) is provided opposite to the second terminal 20 (conducting portion 21), on the front surface of the second insulating member 40. Thus, even in the case where the second insulating member 40 is not limited to a heat-shrinkable tube and an insulating tape but is made of epoxy resin, the stacked terminal unit 5b allows for a reduction in the width of the first insulating member 30 while ensuring the insulation creepage distance between the first terminal 10 and the second terminal 20, which achieves downsizing, as in the first embodiment. Furthermore, it is achieved to alleviate the electric field concentration between the first terminal 10 and the second terminal 20.

### Modification 1-3

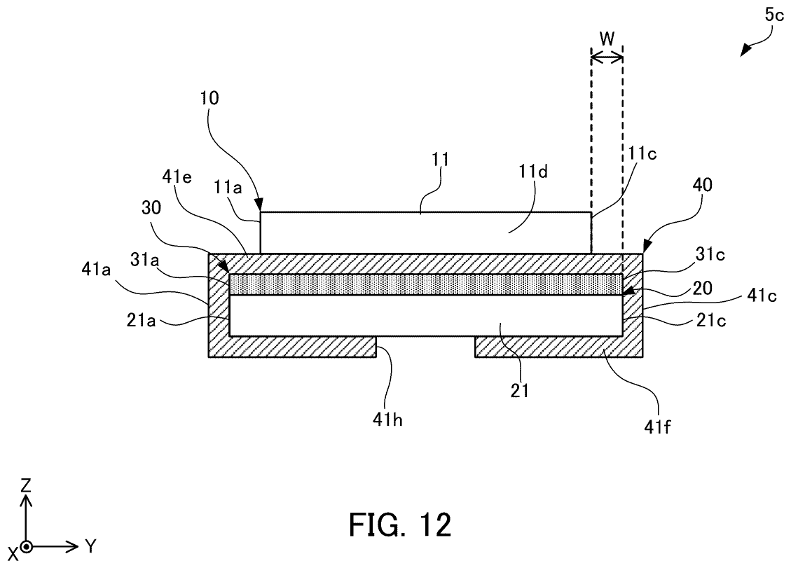

A stacked terminal unit 5c of a modification 1-3 will be described with reference to FIG. 12. FIG. 12 is a widthwise sectional view of the stacked terminal unit included in the semiconductor device according to the first embodiment (modification 1-3). More specifically, the sectional view of FIG. 12 is a view of the stacked terminal unit 5c at a location corresponding to the dash-dotted line X-X of FIG. 4.

Compared to the stacked terminal unit 5 of the first embodiment, the stacked terminal unit 5c of the modification 1-3 is formed so that the second insulating member 40 surrounds, when viewed in the −X direction, the four sides of the second terminal 20 and first insulating member 30 with the insulating edge portion 41a, insulating upper portion 41e, insulating edge portion 41c, and insulating lower portion 41f. Note, however, that the second insulating member 40 does not entirely surround the four-side outer periphery of the second terminal 20 and first insulating member 30. The insulating lower portion 41f of the second insulating member 40 has a gap 41h. In other words, when viewed in the −X direction, the second insulating member 40 surrounds the second terminal 20 and first insulating member 30 in the +Z direction and the ±Y direction, and has a slit (gap 41h) crossing the insulating lower portion 41f covering the rear surface of the second terminal 20 (on the side of the second terminal 20 opposite to the first insulating member 30) in the ±X direction. In this case, for example, the second insulating member 40 may be in the form of a tape, and may surround the four sides of the second terminal 20 and first insulating member 30 while leaving the gap 41h on the rear surface of the second terminal 20.

As in the first embodiment, the stacked terminal unit 5c having the above configuration allows for a reduction in the width of the first insulating member 30 while ensuring the insulation creepage distance between the first terminal 10 and the second terminal 20, which achieves downsizing. Furthermore, it is achieved to alleviate the electric field concentration between the first terminal 10 and the second terminal 20.

In addition, the gap 41h (slit) is formed in the insulating lower portion 41f covering the rear surface of the second terminal 20. This makes it possible to ensure the insulation creepage distances from each of the terminal edge portions 11a and 11c of the first terminal 10 to the rear surface of the second insulating member 40. In this connection, the gap 41h in the insulating lower portion 41f of the second insulating member 40 needs to have such a width in the ±Y direction as to ensure this insulation creepage distance. Therefore, the width of the gap 41h of the insulating lower portion 41f in the ±Y direction is preferably made as narrow as possible.

In addition, as in the modification 1-3, a gap 41h may be formed in the rear surface of the second insulating member 40 provided in each of the stacked terminal unit 5a of the modification 1-1 and the stacked terminal unit 5b of the modification 1-2. This case also makes it possible to ensure the insulation creepage distances from each of the terminal edge portions 11a and 11c of the first terminal 10 to the rear surface of the second insulating member 40.

### Second Embodiment

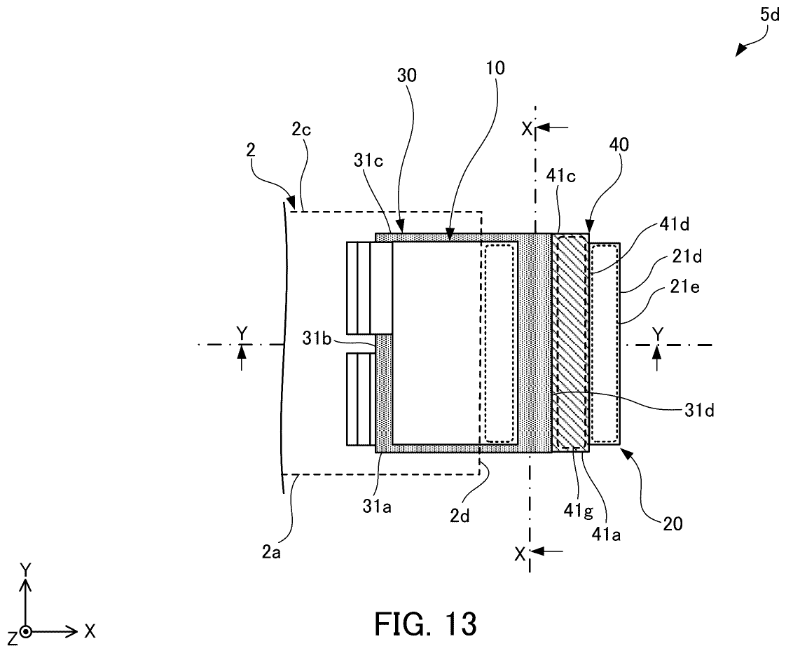

A stacked terminal unit of a second embodiment is a modification of the stacked terminal unit 5 of the first embodiment, in which the first insulating member 30 is provided on the front surface of the second insulating member 40. This stacked terminal unit will be described with reference to FIGS. 13 to 15.

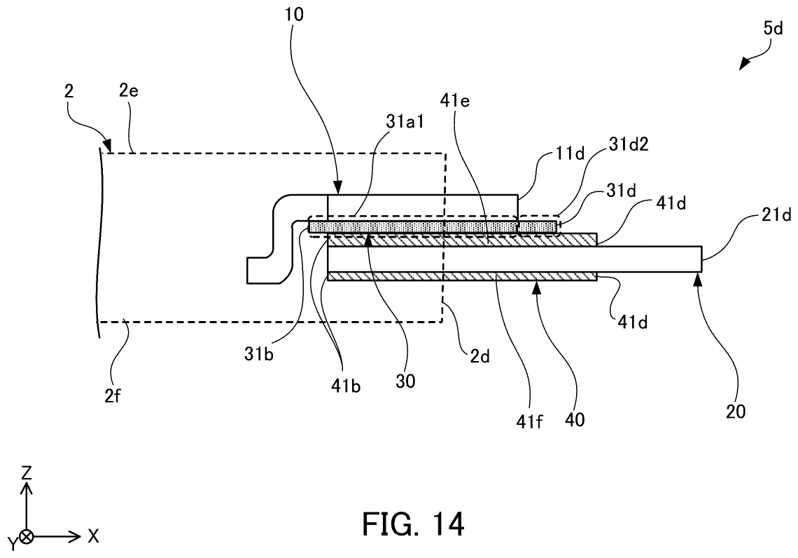

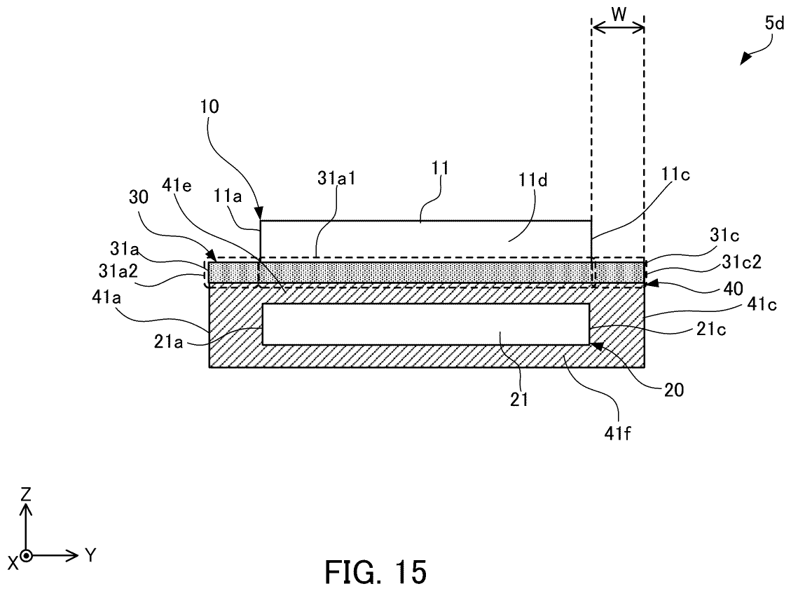

FIG. 13 is a plan view of the stacked terminal unit included in a semiconductor device according to the second embodiment. FIG. 14 is a first lengthwise sectional view of the stacked terminal unit included in the semiconductor device according to the second embodiment. FIG. 15 is a widthwise sectional view of the stacked terminal unit included in the semiconductor device according to the second embodiment. The plan view of FIG. 13 is a view of the stacked terminal unit 5d corresponding to that of FIG. 4. The sectional view of FIG. 14 is a view taken along the dash-dotted line Y-Y of FIG. 13. The sectional view of FIG. 15 is a view taken along the dash-dotted line X-X of FIG. 13.

The stacked terminal unit 5d also includes a first terminal 10, a second terminal 20, a first insulating member 30, and a second insulating member 40. The first terminal 10, second terminal 20, first insulating member 30, and second insulating member 40 are made of the same materials as used in the stacked terminal unit 5 of the first embodiment. In addition, the first terminal 10 (conducting portion 11) has substantially the same width in the ±Y direction as the second terminal 20 (conducting portion 21).

In the stacked terminal unit 5d, the second insulating member 40 entirely surrounds the four-side outer periphery of the second terminal 20, when viewed in the −X direction. The first insulating member 30 and the first terminal 10 are stacked on the front surface of an insulating upper portion 41e of the second insulating member 40 in order.

The second insulating member 40 integrally includes an insulating edge portion 41a, the insulating upper portion 41e, an insulating edge portion 41c, and an insulating lower portion 41f, which entirely surround the four-side outer periphery of the second terminal 20 when viewed in the −X direction (see FIG. 15).

The insulating upper portion 41e of the second insulating member 40 is disposed between the first terminal 10 and the second terminal 20. In addition, the insulating upper portion 41e of the second insulating member 40 is in contact with the entire lower surface of each of a first portion 31a1 and second portions 31a2, 31c2, and 31d2 of the first insulating member 30. The insulating upper portion 41e of the second insulating member 40 covers the front surface of the second terminal 20 across the ±Y direction. In addition, the insulating edge portions 41a and 41c of the second insulating member 40 cover the terminal edge portions 21a and 21c of the conducting portion 21 of the second terminal 20 across the ±Z direction. Still further, the insulating lower portion 41f of the second insulating member 40 covers the rear surface of the conducting portion 21 of the second terminal 20 across the ±Y direction. The insulating edge portions 41a and 41c of the second insulating member 40 are located further outside in the ±Y direction than the terminal edge portions 21a and 21c of the second terminal 20. That is, the second insulating member 40 has a greater width in the ±Y direction than the second terminal 20.

In addition, the second insulating member 40 is substantially uniform in length in the ±X direction throughout. The −X-side insulating inner end portion 41b of the second insulating member 40 is substantially aligned with the end portion of the first terminal 10 (conducting portion 11) opposite to the terminal outer end portion 11d. The −X-side insulating inner end portion 41b of the second insulating member 40 is substantially aligned with the end portion of the second terminal 20 (conducting portion 21) opposite to the terminal outer end portion 21d. In addition, the insulating outer end portion 41d of the second insulating member 40 is located further outside (in the +X direction) than the insulating outer end portion 31d of the first insulating member 30 and further inside (in the −X direction) than the terminal outer end portion 21d of the second terminal 20. In this connection, the front surface of a portion of the second terminal 20 extending outward (in the +X direction) beyond the insulating outer end portion 41d of the second insulating member 40 is an exposed region 21e.

The first insulating member 30 is provided on the front surface of the insulating upper portion 41e of the second insulating member 40. The first insulating member 30 has substantially the same width in the ±Y direction as the second insulating member 40. That is, when viewed in the −X direction, the insulating edge portions 31a and 31c of the first insulating member 30 are aligned with the insulating edge portions 41a and 41c of the second insulating member 40, respectively. Portions (for example, the regions enclosed by broken rectangles of FIG. 15) of the first insulating member 30 extending outward in the ±Y direction beyond the terminal edge portions 11a and 11c of the first terminal 10 by width W are second portions 31a2 and 31c2, respectively. In this connection, in the second embodiment, the rear surfaces of the second portions 31a2 and 31c2 of the first insulating member 30 are covered by the insulating upper portion 41e of the second insulating member 40.

In addition, the insulating inner end portion 31b of the first insulating member 30 extends in the −X direction beyond the insulating inner end portion 41b of the second insulating member 40, the (−X side) end portion of the conducting portion 11 of the first terminal 10 opposite to the terminal outer end portion 11d and the (−X side) end portion of the conducting portion 21 of the second terminal 20 opposite to the terminal outer end portion 21d.

The insulating outer end portion 31d of the first insulating member 30 is located further outside (in the +X direction) than the terminal outer end portion 11d of the first terminal 10 and further inside (in the −X direction) than the insulating outer end portion 41d of the second insulating member 40. A portion (for example, the region enclosed by a broken rectangle of FIG. 14) of the first insulating member 30 extending outward (in the +X direction) beyond the terminal outer end portion 11d of the conducting portion 11 of the first terminal 10 is the second portion 31d2. That is, the second portion 31d2 of the first insulating member 30 is a portion exposed from the case 2 and beyond the conducting portion 11 of the first terminal 10, and the front surface of the second portion 31d2 is an exposed region (reference numeral omitted). In this connection, the portion of the front surface of the second insulating member 40 exposed from the case 2 and beyond the first insulating member 30 is an exposed region 41g.

The present embodiment provides the example where the insulating outer end portion 31d of the first insulating member 30 is located further inside (in the −X direction) than the insulating outer end portion 41d of the second insulating member 40 in plan view. The insulating outer end portion 31d of the first insulating member 30 is not limited thereto, and may be aligned with the insulating outer end portion 41d of the second insulating member 40.

As described above, in the stacked terminal unit 5d of the second embodiment as well, the second portions 31a2, 31c2, and 31d2 of the first insulating member 30 extend outward beyond the terminal edge portions 11a and 11c and terminal outer end portion 11d of the first terminal 10, respectively. More specifically, the extension of the second portions 31a2, 31c2, and 31d2 beyond the first terminal 10 by 0.5 mm or more makes it possible to maintain the insulation between the first terminal 10 and the second terminal 20 more reliably. In addition, the first insulating member 30 has higher insulation than the second insulating member 40, and the first insulating member 30 and second insulating member 40 are provided between the first terminal 10 and the second terminal 20. Therefore, it is possible to keep the distance constant between the first terminal 10 and the second terminal 20, to alleviate the electric field concentration between the first terminal 10 and the second terminal 20 directly below the terminal edge portions 11a and 11c and terminal outer end portion 11d of the first terminal 10, and to maintain the insulation. Therefore, the stacked terminal unit 5d having the above configuration allows for a reduction in the width of the first insulating member 30 while ensuring the insulation creepage distance between the first terminal 10 and the second terminal 20, which achieves downsizing. Furthermore, it is achieved to alleviate the electric field concentration between the first terminal 10 and the second terminal 20. Thus, it is possible to reduce the size of the semiconductor device 1 including the stacked terminal unit 5d while maintaining the reliability of the semiconductor device 1.

In addition, the first terminal 10 of the stacked terminal unit 5d may be chamfered, as in the modification 1-1. The second insulating member 40 of the stacked terminal unit 5d may be made of a thermosetting resin, as in the modification 1-2. Furthermore, a gap 41h may be formed in the rear surface of the second insulating member 40 of the stacked terminal unit 5d, as in the modification 1-3.

### Third Embodiment

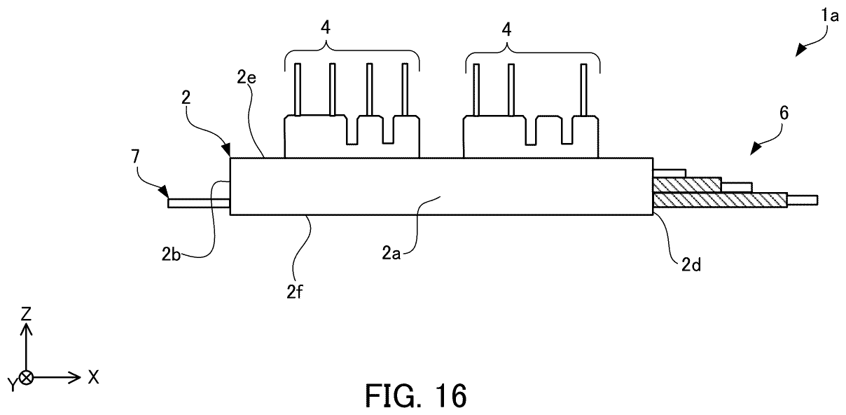

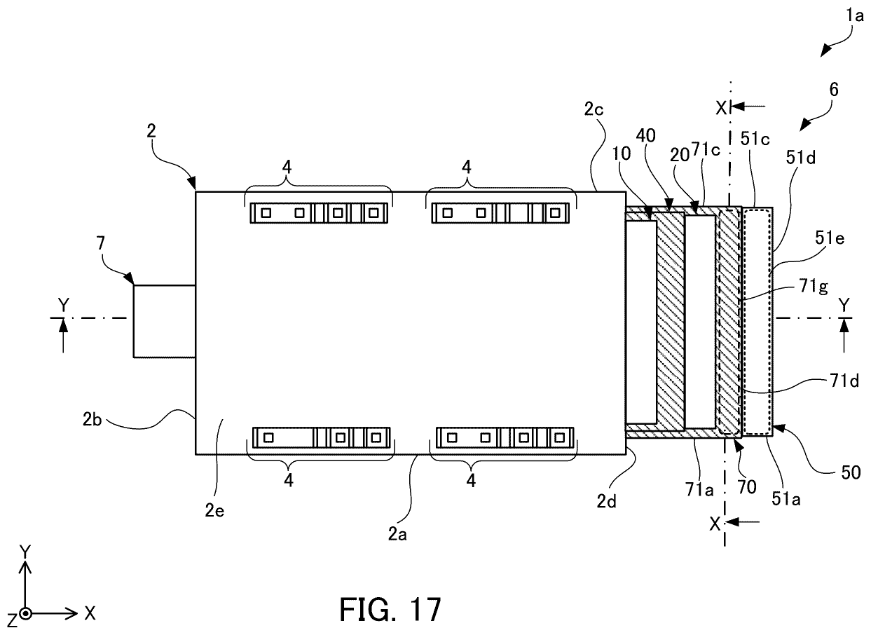

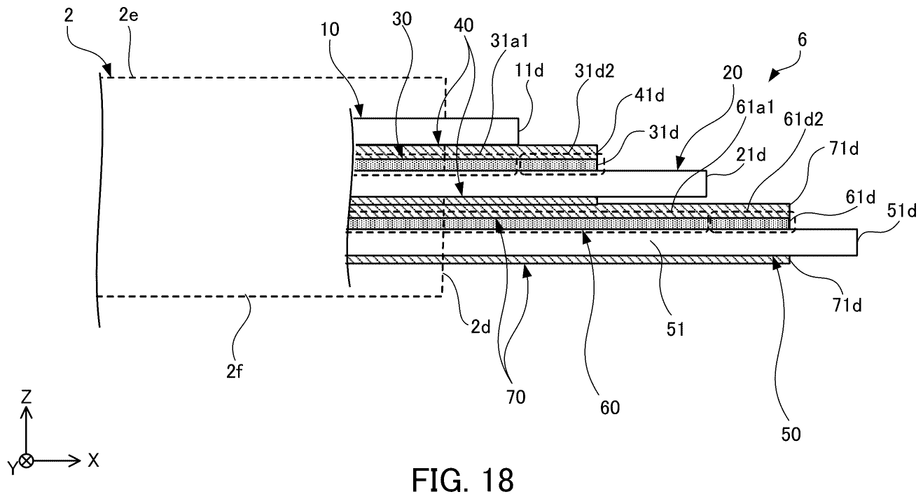

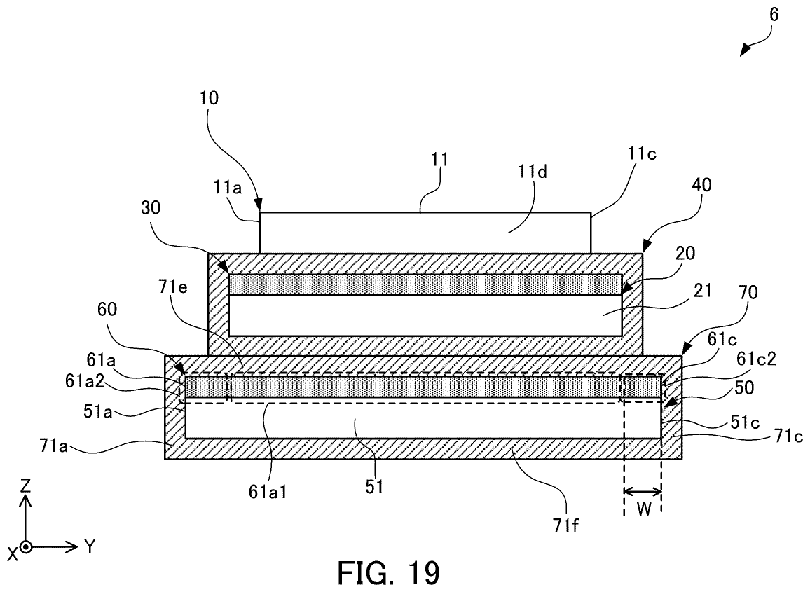

A semiconductor device according to a third embodiment is a modification of the semiconductor device 1 of the first embodiment, in which the stacked terminal unit 5 further includes a third terminal. This semiconductor device will be described with reference to FIGS. 16 to 19. FIG. 16 is a side view of the semiconductor device according to the third embodiment. FIG. 17 is a plan view of the semiconductor device according to the third embodiment. FIG. 18 is a lengthwise sectional view of a stacked terminal unit included in the semiconductor device according to the third embodiment. FIG. 19 is a widthwise sectional view of the stacked terminal unit included in the semiconductor device according to the third embodiment. In this connection, the side view of FIG. 16 illustrates a semiconductor device 1a as seen in the +Y direction. The plan view of FIG. 17 illustrates the semiconductor device 1a as seen in the −Z direction. The sectional view of FIG. 18 is a view taken along the dash-dotted line Y-Y of FIG. 17. The sectional view of FIG. 19 is a view taken along the dash-dotted line X-X of FIG. 17. In this connection, reference numerals for the configurations of the first terminal 10, second terminal 20, first insulating member 30, and second insulating member 40 may be omitted in FIGS. 16 to 19. Refer to FIGS. 4 to 7 for these reference numerals.

The semiconductor device 1a includes at least a case 2, an external terminal 7, control terminals 4, and a stacked terminal unit 6. The case 2 and control terminals 4 have been described in the first embodiment. Compared to the device semiconductor 1, the semiconductor device 1a additionally include control terminals 4 adjacent to and along the side surface 2d on the top surface 2e of the case 2.

The external terminal 7 is made of the same material as the output terminal 3 of the first embodiment. The external terminal 7 is electrically connected to a predetermined conductive pattern of the insulated circuit substrate inside the case 2, and extends outward from the side surface 2b of the case 2 in a direction (in the −X direction) perpendicular to the side surface 2b. A positive terminal (P terminal) and a negative terminal (N terminal) are externally connected to the external terminal 7.

The stacked terminal unit 6 is electrically connected to a predetermined conductive pattern of the insulated circuit substrate inside the case 2, and extends outward from the side surface 2d of the case 2. More specifically, the stacked terminal unit 6 extends in a direction (the +X direction) perpendicular to the side surface 2d. The stacked terminal unit 6 includes three-phase output terminals (U terminal, V terminal, and terminal). This stacked terminal unit 6 additionally includes a third terminal 50, a third insulating member 60, and a fourth insulating member 70 on the rear surface of the second insulating member 40 of the stacked terminal unit 5 of the first embodiment. In the stacked terminal unit 6, the first terminal 10 functions as the U terminal, the second terminal 20 functions as the V terminal, and the third terminal 50 functions as the W terminal.

The third terminal 50 also integrally includes a conducting portion 51, and a linking portion and a joining portion (not illustrated). The third terminal 50 is substantially uniform in thickness throughout. The stacked terminal unit 6 extends outward in the +X direction from the side surface 2d of the case 2. In addition, a portion of the stacked terminal unit 6 extends inward (in the −X direction) from the side surface 2d of the case 2. The inward-extending portion of the stacked terminal unit 6 from the side surface 2d s secured to the case 2. In this case, the stacked terminal unit 6 has an exposed region, which is exposed outside as described below.

The conducting portion 51 is rectangular in plan view and is flat plate-shaped. In plan view, the conducting portion 51 includes terminal edge portions 51a and 51c at respective opposite sides of the rectangular front surface and rear surface thereof, and a terminal outer end portion 51d at the respective tips of the front surface and rear surface. The opposite sides and tips have been described in the first embodiment. The portion of the front surface of the conducting portion 51 extending from the side surface 2d of the case 2 and being exposed beyond the fourth insulating member 70 is an exposed region 51e (see FIG. 17).

In addition, the conducting portion 51 has a greater width in the ±Y direction than the conducting portion 21 of the second terminal 20. That is, the terminal edge portions 51a and 51c of the conducting portion 51 are located further outside in the ±Y direction than the terminal edge portions 21a and 21c of the second terminal 20, respectively.

The linking portion (not illustrated) is formed at the (−X side) end portion of the conducting portion 51 opposite to the terminal outer end portion 51d. The joining portion (not illustrated) is rectangular in plan view and is flat plate-shaped. The joining portion is located closer to the bottom surface 2f of the case 2 than is the conducting portion 51, when viewed in the +Y direction. The joining portion is integrally connected to the conducting portion 51, which is at a different height, through the linking portion. The joining portion is joined to a predetermined conductive pattern of the insulated circuit substrate, In this connection, this joining may not illustrated. be achieved by joining using the above-mentioned bonding material or by ultrasonic joining.

In this connection, these linking portion and joining portion may be formed to be continuous with the conducting portion 51 so as not to overlap the linking portion 12 and joining portion 13 of the first terminal 10 and the linking portion 22 and joining portion 23 of the second terminal 20 in plan view.

The third insulating member 60 is provided between the front surface of the conducting portion 51 of the third terminal 50 and the rear surface of the conducting portion 21 of the second terminal 20. More specifically, the rear surface of the conducting portion 21 of the second terminal 20 is provided on the front surface of the third terminal 50 (conducting portion 51) with the fourth insulating member 70 and second insulating member 40 therebetween. The third insulating member 60 is made of the same material as the first insulating member 30.

The third insulating member 60 includes a third portion 61a1 and fourth portions 61a2, 61c2, and 61d2. In addition, the third insulating member 60 is rectangular in plan view, and includes an insulating edge portion 61a, insulating inner end portion (not illustrated), insulating edge portion 61c, and insulating outer end portion 61d that surround the four sides of each of the front surface and rear surface thereof in plan view. The insulating edge portions 61a and 61c are provided at opposite sides of the third insulating member 60. The opposite sides here are sides that are parallel to the extending direction (the +X direction) of the stacked terminal unit 6. That is, the insulating edge portions 61a and 61c are substantially parallel to the side surfaces 2a and 2c of the case 2, the terminal edge portions 11a and 11c of the first terminal 10, the terminal edge portions 21a and 21c of the second terminal 20, and the terminal edge portions 51a and 51c of the third terminal 50.

The third portion 61a1 of the third insulating member 60 is a portion located between the second terminal 20 and the third terminal 50. In the third embodiment, the third portion 61a1 is located opposite to the lower surface of the conducting portion 21 of the second terminal 20. In addition, in the third embodiment, the third insulating member 60 has substantially the same width in the ±Y direction as the conducting portion 51 of the third terminal 50. That is, the insulating edge portions 61a and 61c of the third insulating member 60 are aligned with the terminal edge portions 51a and 51c of the conducting portion 51 of the third terminal 50, respectively. The third insulating member 60 has a greater width in the ±Y direction than the conducting portion 21 of the second terminal 20. The insulating edge portions 61a and 61c of the third insulating member 60 are located further outside in the ±Y direction than the terminal edge portions 21a and 21c of the conducting portion 21 of the second terminal 20. The portions (for example, the regions enclosed by broken rectangles of FIG. 19) of the third insulating member 60 that extend outward in the ±Y direction beyond the terminal edge portions 21a and 21c of the conducting portion 21 of the second terminal 20 up to the insulating edge portions 61a and 61c are the fourth portions 61a2 and 61c2, respectively. In this connection, the fourth portions 61a2 and 61c2 of the third insulating member 60 extend, by width W, outward (in the ±Y direction) beyond the terminal edge portions 21a and 21c (ends of the bottom surface parallel to the third terminal 50) of the second terminal 20.

The insulating inner end portion (not illustrated) is the −X-side inner end portion of the third insulating member 60. That is, the insulating inner end portion is substantially orthogonal to the side surfaces 2a and 2c of the case 2, the terminal edge portions 21a and 21c of the second terminal 20, and the terminal edge portions 51a and 51c of the third terminal 50. The insulating inner end portion extends in the −X direction beyond the (−X side) end portion of the conducting portion 21 of the second terminal 20 opposite to the terminal outer end portion 21d and the (−X side) end portion of the conducting portion 51 of the third terminal 50 opposite to the terminal outer end portion 51d.

The insulating outer end portion 61d is the +X-side outer end portion of the third insulating member 60. The insulating outer end portion 61d is substantially parallel to the side surfaces 2b and 2d of the case 2, the terminal outer end portion 21d of the second terminal 20, and the terminal outer end portion 51d of the third terminal 50. The insulating outer end portion 61d is located further outside in the +X direction than the terminal outer end portion 21d of the second terminal 20 and further inside in the −X direction than the terminal outer end portion 51d of the third terminal 50. The portion of the front surface of the third insulating member 60 exposed from the case 2 and beyond the conducting portion 21 of the second terminal 20 is an exposed region (reference numeral omitted). Thus, the portion (for example, the region enclosed by a dashed line of FIG. 18) of the third insulating member 60 that extends outward in the +X direction beyond the terminal outer end portion 21d of the conducting portion 21 of the second terminal 20 up to the insulating outer end portion 61d is the fourth portion 61d2. The front surface of the fourth portion 61d2 of the third insulating member 60 corresponds to an exposed region (reference numeral omitted). The length of the fourth portion 61d2 of the third insulating member 60 in the ±X direction may be set so as to maintain the insulation between the terminal outer end portion 21d of the second terminal 20 and the third terminal 50. This length is, for example, around 10 mm.

The fourth insulating member 70 includes a portion (insulating upper portion 71e) disposed between the second terminal 20 and the third terminal 50. Furthermore, the insulating upper portion 71e of the fourth insulating member 70 is in contact with the entire upper surface of each of the third portion 61a1 and fourth portions 61a2, 61c2, and 61d2 of the third insulating member 60. The fourth insulating member 70 may be made of the same material as the second insulating member 40 of the first embodiment.

In the third embodiment, the fourth insulating member 70 includes the insulating upper portion 71e that is in contact with the upper surfaces of the third portion 61a1 and fourth portions 61a2, 61c2, and 61d2, and surrounds the third insulating member 60 and the third terminal 50 together. When viewed in the −X direction, the fourth insulating member 70 integrally includes the insulating upper portion 71e, an insulating edge portion 71a, an insulating edge portion 71c, and an insulating lower portion 71f, and surrounds the third insulating member 60 and the third terminal 50, as illustrated in FIG. 19.

The insulating upper portion 71e of the fourth insulating member 70 entirely covers the front surface of the third insulating member 60 across the ±Y direction. The insulating edge portions 71a and 71c of the fourth insulating member 70 entirely cover the insulating edge portions 61a and 61c of the third insulating member 60 and the terminal edge portions 51a and 51c of the conducting portion 51 of the third terminal 50 across the ±Z direction. In addition, the insulating lower portion 71f of the fourth insulating member 70 entirely covers the rear surface of the conducting portion 51 of the third terminal 50 across the ±Y direction.

The fourth insulating member 70 is substantially uniform in length in the ±X direction throughout. The −X-side end portion of the fourth insulating member 70 is substantially aligned with the end portion of the second terminal 20 (conducting portion 21) opposite to the terminal outer end portion 21d. The −X-side end portion of the fourth insulating member 70 is substantially aligned with the end portion of the third terminal 50 (conducting portion 51) opposite to the terminal outer end portion 51d. In addition, the insulating outer end portion 71d of the fourth insulating member 70 is substantially aligned with the insulating outer end portion 61d of the third insulating member 60. In this connection, the portion of the front surface of the fourth insulating member 70 exposed from the case 2 and beyond the second insulating member 40 and the second terminal 20 is an exposed region 71g.

Therefore, in the semiconductor device 1a including the above stacked terminal unit 6, the fourth portions 61a2, 61c2, and 61d2 of the third insulating member 60 extend outward beyond the terminal edge portions 21a and 21c and terminal outer end portion 21d of the second terminal 20, respectively. The insulating upper portion 71e of the fourth insulating member 70 is in contact with the third portion 61a1 and fourth portions 61a2, 61c2, and 61d2 of the third insulating member 60. This reduces the likelihood of damage to the insulating edge portions 71a and 71c of the fourth insulating member 70. The third insulating member 60 has higher insulation than the fourth insulating member 70, and the third insulating member 60 and the fourth insulating member 70 are provided between the second terminal 20 and the third terminal 50. This makes it possible to keep the distance constant between the second terminal 20 and the third terminal 50. In addition, it is achieved to alleviate the electric field concentration between the second terminal 20 and the third terminal 50 directly below the terminal edge portions 21a and 21c and terminal outer end portion 21d of the second terminal 20, and to maintain the insulation. Thus, the stacked terminal unit 6 having the above configuration allows for a reduction in the width of the third insulating member 60 while ensuring the insulation creepage distance between the second terminal 20 and the third terminal 50, which achieves downsizing.

The following describes a modification of the stacked terminal unit 6 of the third embodiment. In the following modification, a first terminal 10, a second terminal 20, a first insulating member 30, a second insulating member 40, a third terminal 50, and a third insulating member 60 may be made of the same materials as used in the third embodiment, unless otherwise noted.

### Modification 3-1

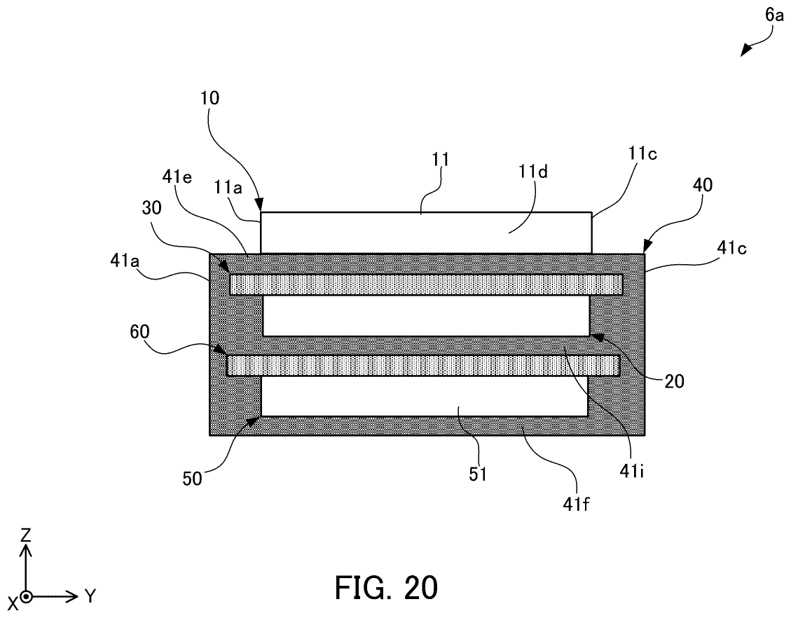

A stacked terminal unit 6a of a modification 3-1 will be described with reference to FIG. 20. FIG. 20 is a widthwise sectional view of a stacked terminal unit included in the semiconductor device according to the third embodiment (modification 3-1). In this connection, the sectional view of FIG. 20 illustrates the stacked terminal unit 6a at a location corresponding to the dash-dotted line X-X of FIG. 17.

The stacked terminal unit 6a of the modification 3-1 is formed so that the second insulating member 40 surrounds the first terminal 10, second terminal 20, first insulating member 30, third terminal 50, and third insulating member 60 of the stacked terminal unit 6 of the third embodiment, as in the modification 1-2.

In the stacked terminal unit 6a, the first terminal 10, second terminal 20, and third terminal 50 have the same width in the ±Y direction. In addition, the first insulating member 30 and the third insulating member 60 have the same width in the ±Y direction and have a greater width in the ±Y direction than the first terminal 10, the second terminal 20, and the third terminal 50. The lengths of the first terminal 10, second terminal 20, first insulating member 30, third terminal 50, and third insulating member 60 in the ±X direction are set as in the stacked terminal unit 6.

The second insulating member 40 includes the insulating edge portion 41a, the insulating upper portion 41e, the insulating edge portion 41c, and the insulating lower portion 41f, which entirely surround the four-side outer periphery of the first insulating member 30, second terminal 20, third insulating member 60, and third terminal 50, when viewed in the −X direction. The second insulating member 40 also includes an insulating middle portion 411 (fourth insulating member) located between the second terminal 20 and the third insulating member 60 when viewed in the −X direction. The second insulating member 40 integrally includes the insulating edge portion 41a, the insulating upper portion 41e, the insulating edge portion 41c, the insulating lower portion 41f, and the insulating middle portion 41i. The second insulating member 40 is made of the same material as the second insulating member 40 of the modification 1-2 as its main component.

The second terminal 20 (conducting portion 21) is provided opposite to the third terminal 50 (conducting portion 21) in the above second insulating member 40. Thus, even in the case where the second insulating member 40 is not limited to a heat-shrinkable tube and an insulating tape but is made of epoxy resin, the stacked terminal unit 6a allows for a reduction in the width of the third insulating member 60 while ensuring the insulation creepage distance between the second terminal 20 and the third terminal 50, which achieves downsizing, as in the third embodiment. Furthermore, it is achieved to alleviate the electric field concentration between the second terminal 20 and the third terminal 50.

In this connection, the modifications 1-1 and 1-3 of the first embodiment are applicable to the stacked terminal unit 6 of the third embodiment. In addition, the stacked terminal unit 5d of the second embodiment may be formed so that the third insulating member 60 and the third terminal 50 surrounded by the fourth insulating member 70 are additionally provided in order on the rear surface of the second insulating member 40, as in the third embodiment.

The disclosed techniques make it possible to maintain insulation between terminals, prevent reliability degradation, and enable downsizing.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a plate-shaped first terminal having opposite upper and lower surfaces that are parallel to each other;
a plate-shaped second terminal having opposite upper and lower surfaces that are parallel to each other, the upper surface of the second terminal facing and being parallel to the lower surface of the first terminal;
a first insulating member including
a first portion being disposed between the lower surface of the first terminal and the upper surface of the second terminal, and
a second portion extending a predetermined distance outward beyond an end of the first terminal in a first direction parallel to the lower surface of the first terminal;
a second insulating member having a contact portion disposed between the lower surface of the first terminal and the upper surface of the second terminal, the contact portion being in contact with both the first portion and the second portion of the first insulating member; and
a case fixing the first terminal, the second insulating member, the first insulating member, and the second terminal,
wherein the first insulating member is in direct contact with one of the first terminal or the second terminals and is not in contact with the other of the first terminal or the second terminals, and
wherein the second insulating member is in contact with the other of the first terminal or the second terminals.

2. The semiconductor device according to claim 1, wherein the contact portion of the second insulating member is disposed between the first insulating member and the lower surface of the first terminal.

3. The semiconductor device according to claim 1, wherein the second insulating member surrounds and fixes the first insulating member and the second terminal.

4. The semiconductor device according to claim 3, wherein the second insulating member is a heat-shrinkable tube or is made of epoxy resin.

5. The semiconductor device according to claim 3, wherein the second insulating member has a lower portion on the lower surface of the second terminal, the lower portion having a slit exposing the lower surface of the second insulating member.

6. The semiconductor device according to claim 1, wherein the lower surface of the first terminal is chamfered at an end portion thereof such that the end portion of the lower surface of the first terminal is rounded, whereby a distance between the end portion and the second insulating member increases as the end portion extends outward from the second portion in a second direction orthogonal to the first direction and parallel to the lower surface of the first terminal.

7. The semiconductor device according to claim 1, wherein the first terminal and the second terminal have a same width in a second direction orthogonal to the first direction and parallel to the lower surface of the first terminal, and the second portion of the first insulating member extends in the second direction further outward than an end portion of the second terminal.

8. The semiconductor device according to claim 1, wherein the second insulating member is disposed between the first insulating member and the upper surface of the second terminal.

9. The semiconductor device according to claim 8, wherein
the second insulating member surrounds the second terminal, and
the first insulating member has an end surface at an end of the second portion, and the end surface of the first insulating member is flush with an end surface of the second insulating member and is orthogonal to the first and second directions.

10. The semiconductor device according to claim 1, wherein the second portion has a width of 0.5 mm or more in the first direction.

11. The semiconductor device according to claim 1, wherein the first insulating member has a higher dielectric breakdown strength than the second insulating member.

12. The semiconductor device according to claim 1, wherein the first insulating member has a higher Young's modulus than the second insulating member.

13. The semiconductor device according to claim 1, wherein a current flows through the first terminal in a direction opposite to a direction of a current flowing through the second terminal.

14. The semiconductor device according to claim 1, further comprising:
a plate-shaped third terminal having opposite upper and lower surfaces that are parallel to each other, the upper surface of the third terminal facing and being parallel to the lower surface of the first terminal;
a third insulating member including
a third portion being disposed between the lower surface of the second terminal and the upper surface of the third terminal, and
a fourth portion extending a predetermined distance outward beyond an end of the second terminal in the first direction; and
a fourth insulating member having a contact portion disposed between the lower surface of the second terminal and the upper surface of the third terminal, the contact portion being in contact with the third portion and the fourth portion of the third insulating member,
wherein the case further fixes the third terminal, the third insulating member, and the fourth insulating member.

15. The semiconductor device according to claim 14, wherein the fourth insulating member surrounds and fixes the third insulating member and the third terminal.

16. The semiconductor device according to claim 15, wherein the fourth insulating member is a heat-shrinkable tube or is made of epoxy resin.

17. The semiconductor device according to claim 14, wherein the fourth insulating member is disposed between the lower surface of the second terminal and the third insulating member.

18. The semiconductor device according to claim 14, wherein the fourth portion has a width of 0.5 mm or more in the first direction.

19. The semiconductor device according to claim 14, wherein a current flows through the third terminal in a direction opposite to a direction of a current flowing through the second terminal.

20. The semiconductor device according to claim 14, wherein
the fourth insulating member surrounds the third terminal,
the fourth insulating member is disposed between the third insulating member and the upper surface of the third terminal, and
the third insulating member has an end surface at an end of the fourth portion, and the end surface of the third insulating member is flush with an end portion of the fourth insulating member and is orthogonal to the first and second direction.
